(19) United States
(12) Patent Application Publication
(10) Pub. No.: US 2025/0048831 A1
(43) Pub. Date: Feb. 6, 2025

(54) ORGANIC ELECTROLUMINESCENT DISPLAY PANEL

(71) Applicant: Beijing Summer Sprout Technology Co., LTD, Beijing (CN)

(72) Inventors: Yurun QI, Beijing (CN); Jing WANG, Beijing (CN); Menglan XIE, Beijing (CN); Ying HOU, Beijing (CN); Huiqing PANG, Beijing (CN); Botong ZUO, Beijing (CN)

(21) Appl. No.: 18/784,208

(22) Filed: Jul. 25, 2024

(30) Foreign Application Priority Data
Jul. 28, 2023 (CN) 202310941947.1

(51) Int. Cl. H10K 50/852; H10K 102/00

(52) U.S. Cl. CPC H10K 50/852; H10K 2102/3026

(57) ABSTRACT

Provided is an organic electroluminescent display panel. The display panel includes a base substrate on which at least two organic electroluminescent devices are disposed. A match of red and green light-emitting materials whose full widths at half maximum of photoluminescence spectra have a difference within a particular range is selected to be applied to red and green light devices of the display panel, ensuring that luminance decay degrees of red light and green light of the display panel are basically the same at a different viewing angle. Thus, an image displayed by the display panel will not become greener or redder for a stronger decay of one of red light and green light so that an image with a relatively good color is presented at a different viewing angle, improving a color cast of the panel at different viewing angles.

### CROSS-REFERENCE TO RELATED APPLICATION(S)

This application claims priority to Chinese Patent Application No. 202310941947.1 filed on Jul. 28, 2023, the disclosure of which is incorporated herein by reference in its entirety.

### TECHNICAL FIELD

The present disclosure relates to a display panel and, in particular, to an organic electroluminescent display panel and an electronic assembly including the organic electroluminescent display panel.

### BACKGROUND

At present, full-color displays are widely applied to our work and life, such as a display of a mobile phone, a display of a computer, and an advertising display in a shopping mall, and the displays are mainly used for displaying texts, graphics, videos, and other information. The full-color displays display various colors by controlling the luminance of RGB sub-pixels. To identify the quality of a full-color display, a viewing angle is also one important characteristic to be considered for evaluating the display quality, in addition to brightness, lifetime, and a white balance effect.

The viewing angle generally refers to a difference between a color displayable by the display at a different viewing angle and a color at a positive viewing angle (when a line of sight of human eyes is perpendicular to a screen, that is, the line of sight of human eyes is at 90° angle to a screen). A greater deviation between the color and/or brightness at a different angle and the color and/or brightness at a positive viewing angle indicates a smaller range of the viewing angle and a larger color cast, causing poor viewing experience at a larger viewing angle. For example, an image looks very real at the positive viewing angle. However, when the image is viewed at a large angle, some colors have too high brightness and other colors have too low brightness because three colors of red, green, and blue have different brightness decays at different viewing angles, causing distortion of image and color.

Currently, active-matrix organic light-emitting diode (AMOLED) has become the mainstream display technology of small and medium screens including the mobile phone. Most of the current AMOLED displays adopt a top-emitting device structure. A microcavity effect in this structure makes the light emission of an OLED device no longer present a Lambertian emission effect. On the contrary, a light intensity at the positive viewing angle is generally greater than that at another viewing angle, that is, the preceding color cast problem is caused. How to reduce the color cast of a display panel is always explored by researchers in the art.

A full width at half maximum of a light-emitting material is one of the important indexes for evaluating performance parameters of the light-emitting material. With the continuous development of OLED materials, a light-emitting material with a relatively narrow full width at half maximum is considered to have higher efficiency and higher color purity and thus is continuously iterated into screens of electronic products. However, the light-emitting material with a narrow full width at half maximum tends to further aggravate the color cast in a top-emitting device. Of course, a panel is not required to be completely free from the color cast in the display field, and the brightness and colors of different pixels in the panel are required to change as closely as possible at different viewing angles, so as to ensure that a white balance of the panel is not affected by a change in the viewing angle. This is also constantly studied by persons in the art.

Patent CN111312775B discloses a pixel unit, a display panel, and a brightness compensation method of the display panel, where the numbers, light-emitting areas, and/or arrangement manners of first-type sub-pixels and second-type sub-pixels in a pixel of the same color in the display panel are set to adjust the decay speed of light of each color, thereby improving the color cast at a viewing angle. However, this application pays no attention to an effect of a relationship between full widths at half maximum of pixels of different colors on brightness decays and does not disclose which relationship between the full widths at half maximum of the pixels of different colors in the panel needs to be set to ensure efficiency and color purity and improve the color cast.

Patent application CN111293149A discloses a display panel and a preparation method thereof, where a light absorption layer is added on a light emission side of a device so that the spectrum on a right side of a maximum emission wavelength of an emission spectrum of the device is absorbed, thereby narrowing the spectrum, increasing a color gamut, and improving a color cast of the device. Similarly, this application pays no attention to an effect of a relationship between full widths at half maximum of pixels of different colors on brightness decays and does not disclose which relationship between the full widths at half maximum of the pixels of different colors in the panel needs to be set to ensure efficiency and color purity and improve the color cast.

In conclusion, how to coordinate the performance of different pixels in the display panel at a large viewing angle to further improve the color cast while ensuring OLED efficiency and color purity is an urgent problem to be solved.

### SUMMARY

The present disclosure aims to provide a series of new organic electroluminescent display panels to solve at least part of the above-mentioned problems. In a new display panel disclosed in the present disclosure, a combination and match of red and green light-emitting materials whose full widths at half maximum have a difference within a particular range are selected to be applied to red and green light devices of the panel, ensuring a consistent luminance decay tendency of the red and green light devices at different angles and improving a color cast of the panel at different angles.

According to an embodiment of the present disclosure, disclosed is an organic electroluminescent display panel comprising a base substrate on which at least two organic electroluminescent devices are disposed;
a first organic electroluminescent device comprising a first anode, a first cathode, and a first light-emitting layer disposed between the first anode and the first cathode, wherein the first light-emitting layer comprises a first light-emitting doped material whose photoluminescence spectrum has a maximum emission wavelength λ1 and a full width at half maximum FWHM1; and
a second organic electroluminescent device comprising a second anode, a second cathode, and a second light-emitting layer disposed between the second anode and the second cathode, wherein the second light-emitting layer comprises a second light-emitting doped material whose photoluminescence spectrum has a maximum emission wavelength λ2 and a full width at half maximum FWHM2;
wherein 500 nm≤λ1<600 nm and λ2≥600 nm; and
FWHM1 and FWHM2 are each less than or equal to 40 nm, and FWHM2−FWHM1≥−15 nm.

According to another embodiment of the present disclosure, further disclosed is an electronic assembly comprising the organic electroluminescent display panel in the preceding embodiment.

In the present disclosure, a match of red and green light-emitting materials whose full widths at half maximum of photoluminescence (PL) spectra have a difference within a particular range is selected to be applied to the red and green light devices of the display panel, ensuring that the luminance decay degrees of red light and green light of the display panel are basically the same at a different viewing angle. Thus, an image displayed by the display panel will not become greener or redder for a stronger decay of one of red light and green light so that an image with a relatively good color is presented at a different viewing angle, improving the color cast of the panel at different viewing angles.

### BRIEF DESCRIPTION OF DRAWINGS

FIG. 1 is a structural diagram of an organic electroluminescent device 100 according to an embodiment of the present disclosure.

FIG. 2a is a structural diagram of a device 200 for red and green light simulation according to the present disclosure.

FIG. 2b is a graph of a refractive index of a hole injection layer (HIL) of a device structure 200 of the present disclosure.

FIG. 2c is a graph of a refractive index of a hole transporting layer (HTL) of a device structure 200 of the present disclosure.

FIG. 2d is a graph of a refractive index of an electron blocking layer (EBL) of a device structure 200 of the present disclosure.

FIG. 2e is a graph of a refractive index of an emissive layer (EML) of a device structure 200 of the present disclosure.

FIG. 2f is a graph of a refractive index of a hole blocking layer (HBL) of a device structure 200 of the present disclosure.

FIG. 2g is a graph of a refractive index of an electron transporting layer (ETL) of a device structure 200 of the present disclosure.

FIG. 2h is a graph of a refractive index of a MgAg cathode of a device structure 200 of the present disclosure.

FIG. 2i is a graph of a refractive index of a capping layer (CPL) of a device structure 200 of the present disclosure.

FIG. 3a is a schematic diagram of spectra S1-100, S1-80, S1-60, S1-40, S1-20, and S2-1 to S2-3 of an organic electroluminescent device designed for simulation according to the present disclosure.

FIG. 3b is a schematic diagram of spectra S3-100, S3-80, S3-60, S3-40, S3-20, and S4-1 to S4-3 of an organic electroluminescent device designed for simulation according to the present disclosure.

FIG. 4a is a schematic diagram of spectra S5 to S10 of an organic electroluminescent device designed for simulation according to the present disclosure.

FIG. 4b is a schematic diagram of luminance decays of simulated devices corresponding to spectra S5 to S10 at a viewing angle of 0° to 60° according to the present disclosure.

FIG. 5a is a schematic diagram of spectra S-520-30, S-520-35, and S-520-40 of an organic electroluminescent device designed for simulation according to the present disclosure.

FIG. 5b is a schematic diagram of spectra S-622-30 and S-622-40 of an organic electroluminescent device designed for simulation according to the present disclosure.

### DETAILED DESCRIPTION

As used herein, “top” means furthest away from a substrate, while “bottom” means closest to the substrate. Where a first layer is described as “disposed over” a second layer, the first layer is disposed further away from the substrate. On the contrary, where the first layer is described as “disposed under” the second layer, the first layer is disposed closer to the substrate. There may be other layers between the first layer and the second layer, unless it is specified that the first layer is “in contact with” the second layer. For example, a cathode may be described as “disposed over” an anode, even though there are various organic layers in between.

As used herein, the term “OLED device” comprises an anode layer, a cathode layer, and one or more organic layers disposed between the anode layer and the cathode layer. The “OLED device” may be a bottom-emitting device (bottom emission) that emits light from the side of an anode, a top-emitting device (top emission) that emits light from the side of a cathode, or a double-sided light-emitting device that emits light from the anode and the cathode at the same time.

As used herein, the term “encapsulation layer” may be a thin film encapsulation with a thickness of less than 100 micrometers, which includes one or more thin films disposed directly on the device or may be a cover glass adhered to the substrate.

As used herein, the term “color coordinates” refers to the corresponding coordinates in the CIE 1931 color space.

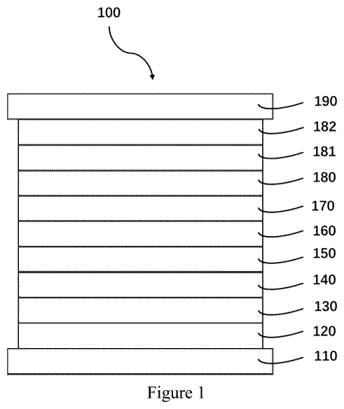

The structure of a typical top-emitting OLED device is shown in FIG. 1. An OLED device 100 includes an anode 110, a hole injection layer (HIL) 120, a hole transporting layer (HTL) 130, an electron blocking layer (EBL) 140 (also referred to as a prime layer), an emissive layer (EML) 150, a hole blocking layer (HBL) 160 (optional), an electron transporting layer (ETL) 170, an electron injection layer (EIL) 180, a cathode 181, a capping layer 182, and an encapsulation layer 190. The anode 110 is a material or a combination of materials having a high reflectivity, including, but not limited to, Ag, Al, Ti, Cr, Pt, Ni, TiN, and a combination of the above materials with ITO and/or MoOx (molybdenum oxide). Generally, the reflectivity of the anode is greater than 50%; preferably, the reflectivity of the anode is greater than 70%; more preferably, the reflectivity of the anode is greater than 80%. The cathode 181 should be a translucent or transparent conductive material, including, but not limited to, a MgAg alloy, MoOx, Yb, Ca, ITO, IZO, or a combination thereof, and the average transmittance of the cathode for light having a wavelength in a visible light region is greater than 15%; preferably, the average transmittance of the cathode for light having a wavelength in the visible light region is greater than 20%; more preferably, the average transmittance of the cathode for light having a wavelength in the visible light region is greater than 25%. The hole injection layer 120 may be a single material layer such as commonly used HATCN. The hole injection layer 120 may also be a hole transporting material doped with a certain proportion of conductive p-type doped material, where the doping proportion is generally not higher than 5% and commonly between 1% and 3%. The EBL 140 is optional. However, to better match an energy level of a host material, a device structure with the EBL is generally adopted. The thickness of the hole transporting layer is generally between 100 nm and 200 nm. Since the top-emitting device has a microcavity effect, the microcavity of the device is usually adjusted by adjusting the thickness of the hole transporting layer. For example, to achieve the best microcavity effect of the top-emitting OLED device, that is, to reach a maximum value CEₘₐₓ of current efficiency, generally, the thickness of the EBL is fixed and the thickness of the HTL is adjusted to adjust the microcavity. The study of a color cast herein is based on an emission point corresponding to the maximum value of the current efficiency. Apparently, those skilled in the art can understand that when two top-emitting devices differ only in that different materials are used in one organic layer, for example, different organic materials are only used in the EBL (other functional layers use the same materials), since the different organic materials in the EBL may have slightly different refractive indexes, the optimal microcavity lengths of the two top-emitting devices may be slightly different.

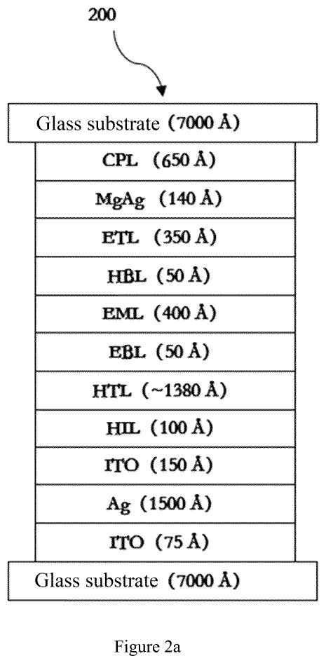

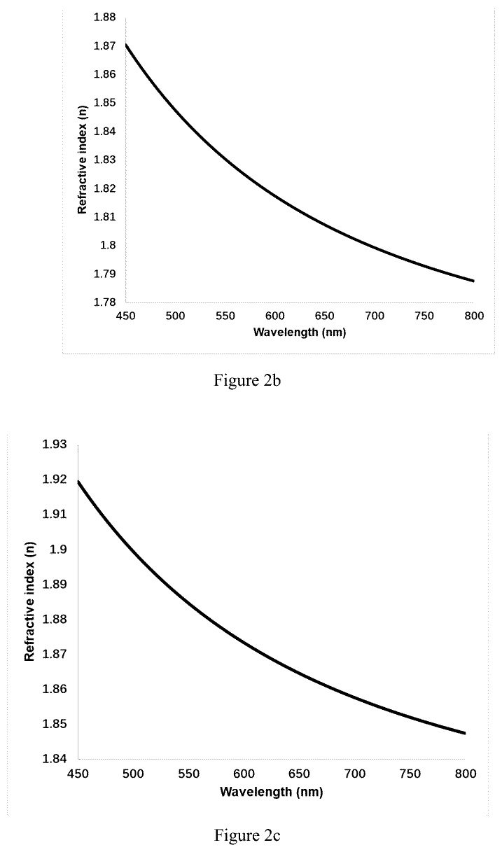

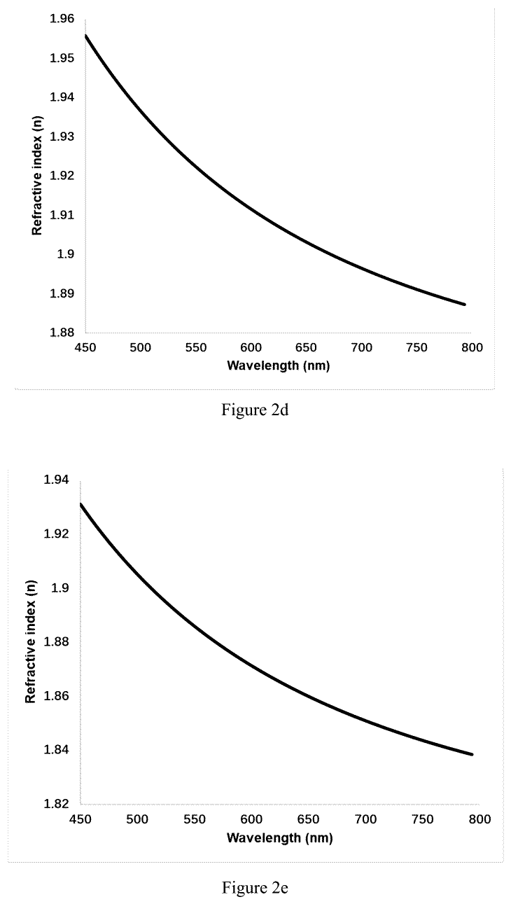

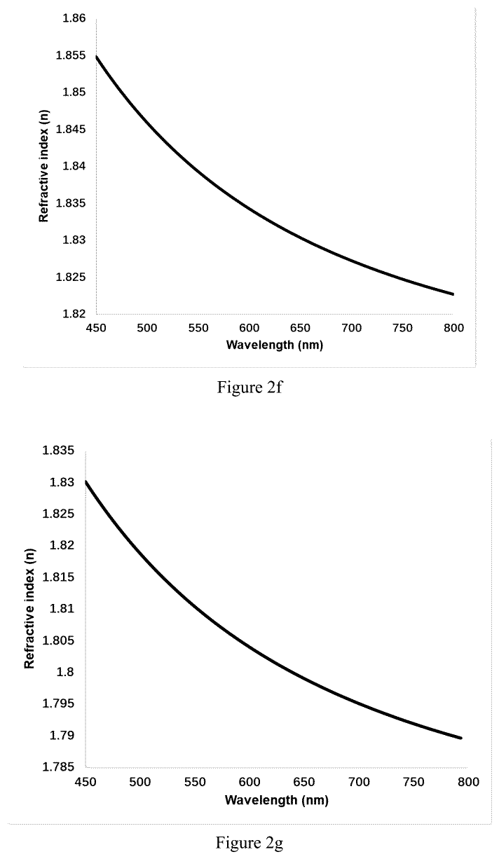

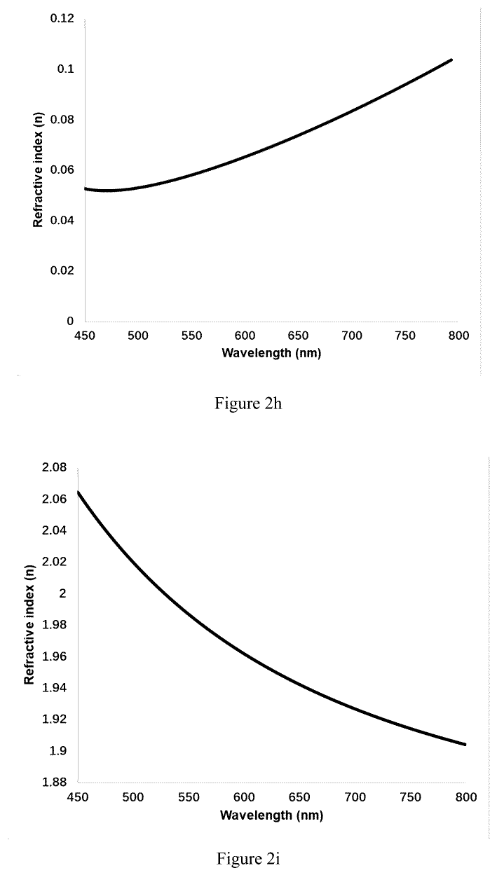

As used herein, the term “simulation” refers to optical simulation performed only through the refractive index curves and thicknesses of various layers of materials in the device, excluding electrical simulation. Simulation software used in the present disclosure is Setfos 5.1.1 semiconductor thin-film optical simulation software developed by FLUXiM. A structural diagram of a device for simulation is shown in FIG. 2a. Specifically, on a glass substrate with a thickness of 7000 Å, a first electrode (that is, an anode) uses a three-layer structure of ITO (75 Å)/Ag (1500 Å)/ITO (150 Å); an HIL is jointly formed by Compounds HT and HI (at a weight ratio of 97:3) and has a thickness of 100 Å; an HTL is formed by Compound HT, and the thickness of the HTL is an optimized thickness of about 1380 Å since the HTL is a microcavity adjustment layer; on the HTL, an EBL is formed by Compound EB-2 and has a thickness of 50 Å; on the EBL, a green EML is jointly formed by Compound GH-1, Compound GH-2, and a green organic light-emitting doped material (at a weight ratio of 48:48:4) or a red EML is jointly formed by Compound RH-1 and a red organic light-emitting doped material (at a weight ratio of 96:4), the EML has a thickness of 400 Å, and during optical simulation, the PL spectrum of the light-emitting doped material may be substituted into the EML for simulation; on the EML, an HBL is formed by Compound HB and has a thickness of 50 Å; on the HBL, an ETL is formed by Compound ET and Liq (at a weight ratio of 40:60) and has a thickness of 350 Å; on the ETL, a second electrode (that is, a cathode) is formed by a MgAg alloy (where a weight ratio of Mg:Ag is 10:90) and has a thickness of 140 Å; on the cathode, a CPL is formed by Compound CPL-1 and has a thickness of 650 Å; and on the CPL, glass with a thickness of 7000 Å is used as an encapsulation layer. The specific structures of the above compounds are described hereinafter. In the software, a light-emitting region (Position) is set to 0.5 and a conversion efficiency factor is set to 0.7. Since Setfos 5.1.1 is optical simulation software, only the thicknesses and refractive indexes of layers in the device structure need to be determined during the simulation (the refractive index of each organic layer is the corresponding refractive index when the thickness of the material is 300 Å). Therefore, the materials of the above layers are only examples and are not limiting. The PL spectrum data of the organic light-emitting doped material used in the EML are inputted into the simulation software so that performance changes of the device caused by organic light-emitting doped materials with different PL spectra can be simulated. Additionally, as is known to those skilled in the art, during the optical simulation, only an optical parameter is considered and no electrical factor (for example, internal quantum efficiency or external quantum efficiency of different light-emitting doped materials) is considered. Therefore, different light-emitting doped materials have the same external quantum efficiency by default in the simulation.

As used herein, a “refractive index”, that is, an optical refractive index (n), refers to the ratio of a propagation speed of light in vacuum to a propagation speed of light in a medium (material). The refractive indexes of organic materials and the cathode layer herein are tested by the following method: a material with a thickness of 30 nm is deposited on a silicon wafer in an Angstrom Engineering evaporator, and a refractive index curve of the material at a wavelength of 450 nm to 800 nm is tested through an ellipsometer of BEIJING ELLITOP. The refractive index curves of the layers of the device structure 200 used in simulation are shown in FIGS. 2b to 2i. The glass substrate Glass, ITO, and Ag use the refractive index curves contained in the software.

As used herein, the PL spectrum of the organic light-emitting doped material is tested by the following method: the PL spectrum and full width at half maximum data of a material to be tested are tested using a fluorescence spectrophotometer F98 produced by SHANGHAI LENGGUANG TECHNOLOGY CO., LTD. Specifically, a sample of the material to be tested is prepared into a solution with a concentration of 1×10⁻⁶ mol/L with HPLC-grade toluene, the prepared solution is deoxygenated through nitrogen introduction for 5 minutes and then excited by light with a wavelength of 500 nm at room temperature (298 K), the emission spectrum is measured, and the FWHM is directly read from the spectrum.

As used herein, a “shoulder(shoulders)” of the spectrum means a shoulder on the right side of the spectrum, which is caused by an energy level of a vibration of electrons.

As used herein, the “corresponding luminance L0 at 0°” refers to a luminance value corresponding to CEₘₐₓ of the tested device at a viewing angle of 0° (that is, a positive viewing angle), and the “corresponding luminance L30 at 30°” refers to a luminance value corresponding to CEₘₐₓ of the tested device at a viewing angle of 30°. The “luminance decay value D” refers to a value obtained by dividing the luminance L30 at the viewing angle of 30° by the luminance L0 at the viewing angle of 0°. In the display industry, this value is commonly used for representing a luminance decay of the device as the viewing angle changes. For example, at the same viewing angle, the larger D indicates a smaller luminance decay of the device. Unit of luminance: nits.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, a substituted hydroxyl, a substituted sulfanyl, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, hydroxyl, sulfanyl, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

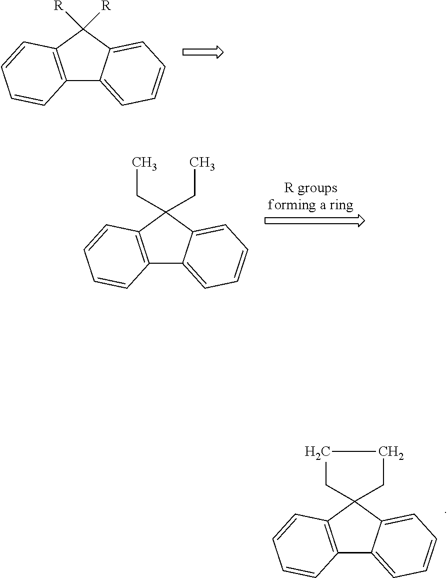

The expression that adjacent substituents can be optionally joined to form a ring is also intended to mean that two substituents bonded to carbon atoms which are directly bonded to each other are joined to each other via a chemical bond to form a ring, which can be exemplified by the following formula:

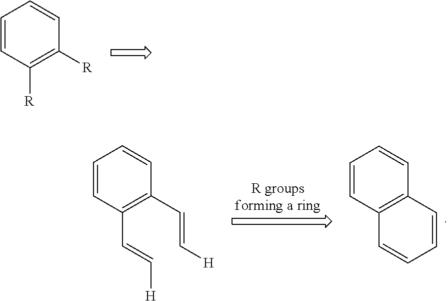

The expression that adjacent substituents can be optionally joined to form a ring is also intended to mean that two substituents bonded to further distant carbon atoms are joined to each other via a chemical bond to form a ring, which can be exemplified by the following formula:

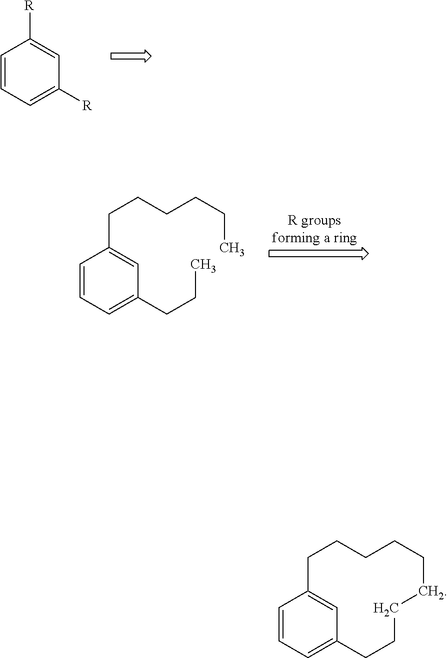

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

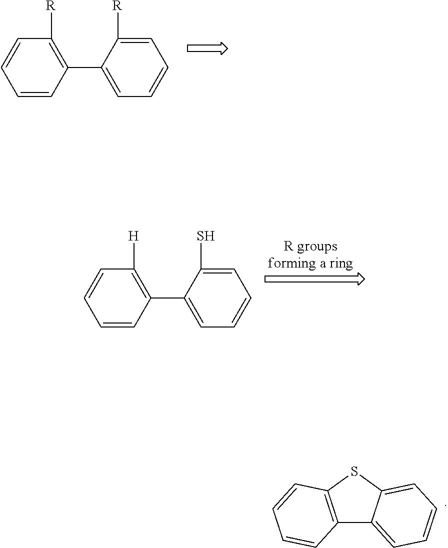

According to an embodiment of the present disclosure, disclosed is an organic electroluminescent display panel comprising a base substrate on which at least two organic electroluminescent devices are disposed;
a first organic electroluminescent device comprising a first anode, a first cathode, and a first light-emitting layer disposed between the first anode and the first cathode, wherein the first light-emitting layer comprises a first light-emitting doped material whose photoluminescence spectrum has a maximum emission wavelength λ1 and a full width at half maximum FWHM1; and
a second organic electroluminescent device comprising a second anode, a second cathode, and a second light-emitting layer disposed between the second anode and the second cathode, wherein the second light-emitting layer comprises a second light-emitting doped material whose photoluminescence spectrum has a maximum emission wavelength λ2 and a full width at half maximum FWHM2;
wherein 500 nm≤λ1<600 nm and λ2≥600 nm; and
FWHM1 and FWHM2 are each less than or equal to 40 nm, and FWHM2−FWHM1≥−15 nm.

According to an embodiment of the present disclosure, 15 nm≥FWHM2−FWHM1≥−15 nm.

According to an embodiment of the present disclosure, 8 nm≥FWHM2−FWHM1≥−8 nm.

According to an embodiment of the present disclosure, 5 nm≥FWHM2−FWHM1≥−5 nm.

According to an embodiment of the present disclosure, 3 nm≥FWHM2−FWHM1≥−3 nm.

According to an embodiment of the present disclosure, FWHM2−FWHM1≥0.

According to an embodiment of the present disclosure, FWHM2−FWHM1≥5.

According to an embodiment of the present disclosure, FWHM2−FWHM1≥10.

According to an embodiment of the present disclosure, at least one of FWHM1 and FWHM2 is less than or equal to 35 nm.

According to an embodiment of the present disclosure, at least one of FWHM1 and FWHM2 is less than or equal to 30 nm.

According to an embodiment of the present disclosure, 20 nm≤FWHM1≤30 nm and 20 nm≤FWHM2≤30 nm.

According to an embodiment of the present disclosure, 500 nm≤λ1<560 nm.

According to an embodiment of the present disclosure, 500 nm≤λ1<535 nm.

According to an embodiment of the present disclosure, 515 nm≤λ1<535 nm.

According to an embodiment of the present disclosure, 600 nm≤λ2<650 nm.

According to an embodiment of the present disclosure, 610 nm≤λ2<640 nm.

According to an embodiment of the present disclosure, 615 nm≤λ2<640 nm.

According to an embodiment of the present disclosure, the first organic electroluminescent device and the second organic electroluminescent device are each a top-emitting device.

According to an embodiment of the present disclosure, the first organic electroluminescent device comprises a first capping layer and the second organic electroluminescent device comprises a second capping layer.

According to an embodiment of the present disclosure, the first capping layer and the second capping layer have the same material and/or thickness.

According to an embodiment of the present disclosure, the first cathode and the second cathode have the same thickness and/or material.

According to an embodiment of the present disclosure, the first capping layer and the second capping layer are the same capping layer.

According to an embodiment of the present disclosure, the first cathode and the second cathode are the same electrode.

According to an embodiment of the present disclosure, the first cathode and the second cathode each comprise Yb, Mg, Ag, MoOx, Yb, Ca, ITO, IZO, or a combination thereof.

According to an embodiment of the present disclosure, the first cathode and the second cathode each comprise a composition of Mg and Ag, and the mass ratio of Mg to Ag in the composition is 0.5:9.5-2:8.

According to an embodiment of the present disclosure, the first anode and the second anode are each selected from Ag, Al, Ti, Cr, Pt, Ni, TiN, ITO, MoOx, or a combination thereof.

According to an embodiment of the present disclosure, the anode has a reflectivity of greater than 50%.

According to an embodiment of the present disclosure, the anode has a reflectivity of greater than 70%.

According to an embodiment of the present disclosure, the first light-emitting doped material and the second light-emitting doped material are each a phosphorescent doped material.

According to an embodiment of the present disclosure, a third organic electroluminescent device is further comprised on the base substrate, wherein the third organic electroluminescent device comprises a third light-emitting layer, and the third light-emitting layer comprises a third light-emitting doped material whose photoluminescence spectrum has a maximum emission wavelength λ3 and a full width at half maximum FWHM3, wherein FWHM3<35 nm, 400≤λ3<500 nm, and FWHM1−FWHM3≥−15 nm.

According to an embodiment of the present disclosure, FWHM3≤30 nm.

According to an embodiment of the present disclosure, FWHM3≤28 nm.

According to an embodiment of the present disclosure, FWHM3≤25 nm.

According to an embodiment of the present disclosure, 15 nm≥FWHM1−FWHM3≥−15 nm.

According to an embodiment of the present disclosure, 3 nm≥FWHM1−FWHM3≥−3 nm.

According to an embodiment of the present disclosure, FWHM1−FWHM3≥0 nm.

According to an embodiment of the present disclosure, the third light-emitting layer may further comprise a fourth light-emitting doped material, and at least one of the fourth light-emitting doped material and the third light-emitting doped material is selected from a phosphorescent doped material.

According to an embodiment of the present disclosure, the base substrate is selected from glass, polyimide, or a silicon wafer.

According to an embodiment of the present disclosure, a luminance decay value of the first organic electroluminescent device at a viewing angle of 30° is D1 and a luminance decay value of the second organic electroluminescent device at a viewing angle of 30° is D2;
wherein −15%≤D1−D2≤15%.

According to an embodiment of the present disclosure, −10%≤D1−D2≤10%.

According to an embodiment of the present disclosure, the shoulder is a low-intensity peak(s) that appear(s) on one or two sides of the main peak of the spectrum.

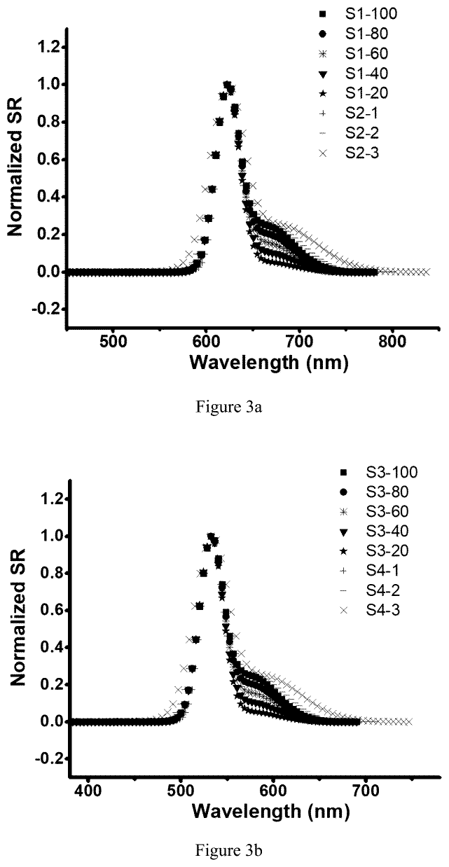

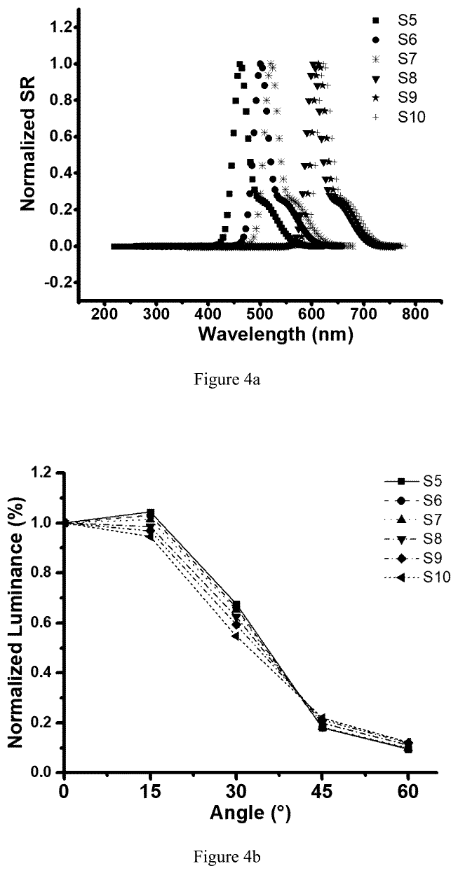

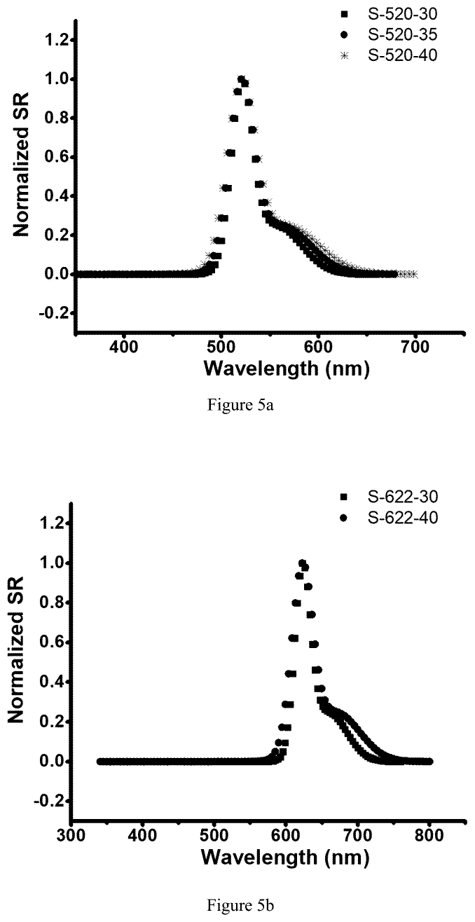

According to an embodiment of the present disclosure, in FIG. 3a to 3b, FIG. 4a, and FIG. 5a to 5b, the shoulder is the low-intensity peak on the right side of the main peak of the spectrum.

According to an embodiment of the present disclosure, the phosphorescent doped material is a metal complex having a general formula of M(Lₐ)ₘ(L_{b})ₙ(L_{c})_{q}; wherein
the metal M is selected from a metal with a relative atomic mass greater than 40;
Lₐ, L_{b}, and Lₑ are a first ligand, a second ligand, and a third ligand coordinated to the metal M, respectively; Lₐ, L_{b}, and Lₑ may be the same or different;
Lₐ, L_{b}, and Lₑ can be optionally joined to form a multidentate ligand;
m is 1, 2, or 3, n is 0, 1, or 2, q is 0, 1, or 2, and m+n+q is equal to an oxidation state of the metal M; when m is greater than or equal to 2, multiple Lₐ may be the same or different; when n is 2, two L_{b} may be the same or different; when q is 2, two Lₑ may be the same or different;
the ligand Lₐ is, at each occurrence identically or differently, selected from a structure represented by Formula 2 or Formula 3:

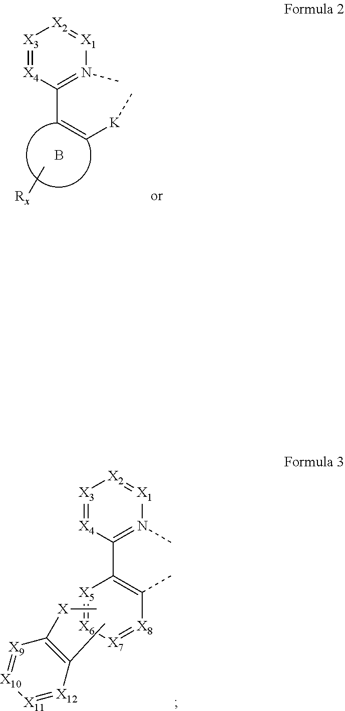

wherein
the ring B is, at each occurrence identically or differently, selected from a five-membered unsaturated carbocyclic ring, an aromatic ring having 6 to 30 carbon atoms, or a heteroaromatic ring having 3 to 30 carbon atoms; in Formula 2, Rₓ represents, at each occurrence identically or differently, mono-substitution, multiple substitutions, or non-substitution;
K is selected from a single bond, O, or S;
X is selected from the group consisting of O, S, Se, NR₂, CR₂R₂, and SiR₂R₂; when two R₂ are present at the same time, the two R₂ may be the same or different;
X₁ to X₁₂ are, at each occurrence identically or differently, selected from C, CRₓ, or N;
R₂ and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
in Formula 2, adjacent substituents can be optionally joined to form a ring;
in Formula 3, adjacent substituents can be optionally joined to form a ring; and
the ligands L_{b} and L_{c} are, at each occurrence identically or differently, selected from a monoanionic bidentate ligand.

Herein, the expression that “in Formula 2, adjacent substituents can be optionally joined to form a ring” is intended to mean that any one or more of groups of adjacent substituents in Formula 2, such as two substituents Rₓ, can be joined to form a ring. Obviously, it is also possible that none of these substituents are joined to form a ring.

Herein, the expression that “in Formula 3, adjacent substituents can be optionally joined to form a ring” is intended to mean that any one or more of groups of adjacent substituents in Formula 3, such as two substituents Rₓ and adjacent substituents R₂ and Rₓ, can be joined to form a ring. Obviously, it is also possible that none of these substituents are joined to form a ring.

According to an embodiment of the present disclosure, the ligand Lₐ is, at each occurrence identically or differently, selected from a structure represented by Formula 2-1, Formula 2-2, Formula 4, or Formula 5:

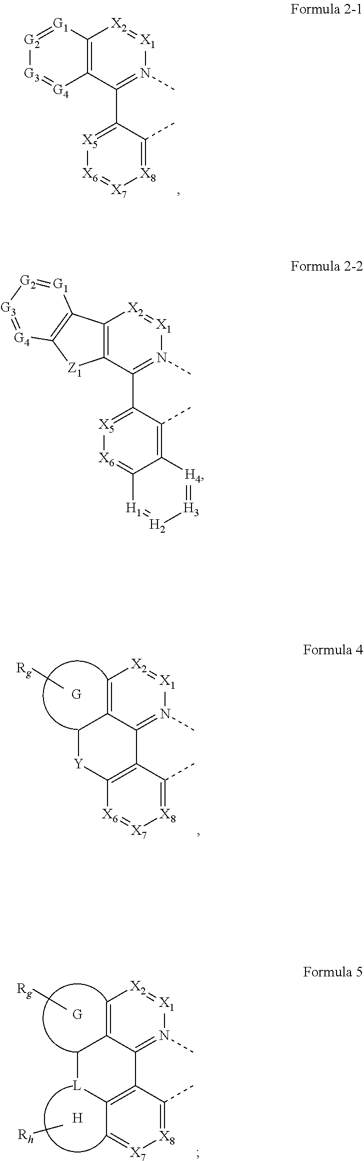

wherein
X₁, X₂, and X₅ to X₈ are, at each occurrence identically or differently, selected from CRₓ or N;
G₁ to G₄ are, at each occurrence identically or differently, selected from CR_{g} or N; H₁ to H₄ are, at each occurrence identically or differently, selected from CRₕ or N;
Z₁ is selected from the group consisting of O, S, Se, NR₂, CR₂R₂, SiR₂R₂, and GeR₂R₂; when two R₂ are present at the same time, the two R₂ are the same or different;
the ring G is, at each occurrence identically or differently, selected from a five-membered unsaturated carbocyclic ring, an aromatic ring having 6 to 30 carbon atoms, or a heteroaromatic ring having 3 to 30 carbon atoms;
the ring H is, at each occurrence identically or differently, selected from a heterocyclic ring having 2 to 30 carbon atoms or a heteroaromatic ring having 2 to 30 carbon atoms;
R_{g} and Rₕ represent, at each occurrence identically or differently, mono-substitution, multiple substitutions, or non-substitution;
Y is selected from the group consisting of O, S, Se, SiR₃R₃, GeR₃R₃, NR₃, and PR₃; when two R₃ are present at the same time, the two R₃ may be the same or different;
L is, at each occurrence identically or differently, selected from B, N, or P;
R₂, R₃, Rₓ, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
in Formula 2-1, adjacent substituents can be optionally joined to form a ring;
in Formula 2-2, adjacent substituents can be optionally joined to form a ring;
in Formula 4, adjacent substituents can be optionally joined to form a ring; and
in Formula 5, adjacent substituents can be optionally joined to form a ring.

Herein, the expression that “in Formula 2-1, adjacent substituents can be optionally joined to form a ring” is intended to mean that any one or more of groups of adjacent substituents in Formula 2-1, such as two substituents Rₓ, two substituents R_{g}, two substituents Rₓ, and adjacent substituents R_{g} and Rₓ, can be joined to form a ring. Obviously, it is also possible that none of these substituents are joined to form a ring.

Herein, the expression that “in Formula 2-2, adjacent substituents can be optionally joined to form a ring” is intended to mean that any one or more of groups of adjacent substituents in Formula 2-2, such as two substituents Rₓ, two substituents Rₕ, two substituents R_{g}, two substituents R₂, adjacent substituents R₂ and Rₓ, adjacent substituents R_{g} and R₂, adjacent substituents R_{g} and Rₓ, and adjacent substituents Rₕ and Rₓ, can be joined to form a ring. Obviously, it is also possible that none of these substituents are joined to form a ring.

Herein, the expression that “in Formula 4, adjacent substituents can be optionally joined to form a ring” is intended to mean that any one or more of groups of adjacent substituents in Formula 4, such as two substituents Rₓ, two substituents R_{g}, two substituents R₃, adjacent substituents R₃ and Rₓ, adjacent substituents R₃ and Rₕ, and adjacent substituents R_{g} and Rₓ, can be joined to form a ring. Obviously, it is also possible that none of these substituents are joined to form a ring.

Herein, the expression that “in Formula 5, adjacent substituents can be optionally joined to form a ring” is intended to mean that any one or more of groups of adjacent substituents in Formula 5, such as two substituents Rₓ, two substituents R_{g}, two substituents Rₕ, adjacent substituents Rₕ and Rₓ, and adjacent substituents R_{g} and Rₓ, can be joined to form a ring. Obviously, it is also possible that none of these substituents are joined to form a ring.

According to an embodiment of the present disclosure, in Formula 2-1, at least one of X₁ and X₂ is selected from CRₓ, and Rₓ is selected from deuterium.

According to an embodiment of the present disclosure, in Formula 2-1, X₁ and X₂ are, at each occurrence identically or differently, selected from CRₓ, and Rₓ is selected from deuterium.

According to an embodiment of the present disclosure, the ligand Lₐ has a structure represented by Formula 4-1:

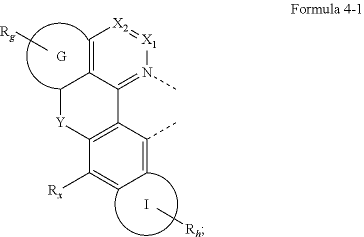

wherein the ring G and the ring I are, at each occurrence identically or differently, selected from a five-membered unsaturated carbocyclic ring, an aromatic ring having 6 to 30 carbon atoms, or a heteroaromatic ring having 3 to 30 carbon atoms;
Y is selected from the group consisting of O, S, Se, SiR₃R₃, GeR₃R₃, NR₃, and PR₃; when two R₃ are present at the same time, the two R₃ may be the same or different;
X₁ and X₂ are, at each occurrence identically or differently, selected from CRₓ or N;
R_{g} and Rₕ represent, at each occurrence identically or differently, mono-substitution, multiple substitutions, or non-substitution;
R_{g}, Rₕ, R₃, and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof, and
in Formula 4-1, adjacent substituents R_{g}, Rₕ, R₃, and Rₓ can be optionally joined to form a ring.

In this embodiment, the expression that “in Formula 4-1, adjacent substituents R_{g}, Rₕ, R₃, and Rₓ can be optionally joined to form a ring” is intended to mean that any one or more of groups of adjacent substituents in Formula 4-1, such as two substituents Rₓ, two substituents R_{g}, two substituents Rₕ, two substituents R₃, adjacent substituents Rₕ and Rₓ, adjacent substituents R₃ and Rₓ, and adjacent substituents R₃ and R_{g}, can be joined to form a ring. Obviously, it is also possible that none of these substituents are joined to form a ring.

According to an embodiment of the present disclosure, the ligand Lₐ is, at each occurrence identically or differently, selected from the group consisting of the following structures:

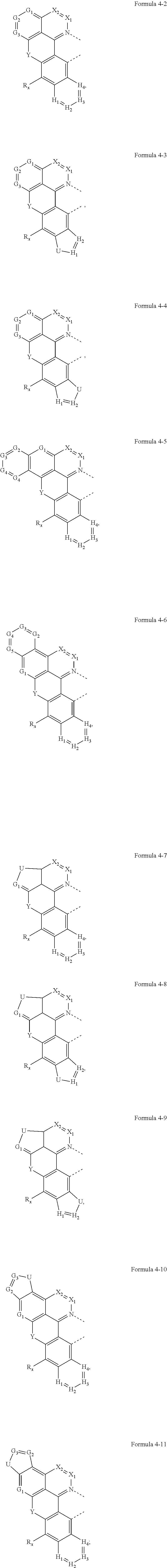

wherein
Y is selected from the group consisting of O, S, Se, SiR₃R₃, GeR₃R₃, NR₃, and PR₃; when two R₃ are present at the same time, the two R₃ may be the same or different;
U is, at each occurrence identically or differently, selected from O, S, Se, CRᵤRᵤ, SiRᵤRᵤ, PRᵤ, or NRᵤ; when two Rᵤ are present at the same time, the two Rᵤ are the same or different;
G₁ to G₅ are, at each occurrence identically or differently, selected from CR_{g} or N;
H₁ to H₄ are, at each occurrence identically or differently, selected from CRₕ or N;
X₁ and X₂ are, at each occurrence identically or differently, selected from CRₓ or N;
R₃, Rₓ, R_{g}, Rₕ, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof, and
in Formula 4-2 to Formula 4-11, adjacent substituents R₃, Rₓ, R_{g}, Rₕ, Rᵤ can be optionally joined to form a ring.

In this embodiment, the expression that “in Formula 4-2 to Formula 4-11, adjacent substituents R₃, Rₓ, R_{g}, Rₕ, Rᵤ can be optionally joined to form a ring” is intended to mean that any one or more of groups of adjacent substituents in Formula 4-2 to Formula 4-11, such as two substituents Rₓ, two substituents R_{g}, two substituents Rₕ, two substituents Rᵤ, two substituents R₃, adjacent substituents Rₕ and Rₓ, adjacent substituents R₃ and Rₓ, adjacent substituents R₃ and R_{g}, and adjacent substituents Rᵤ and R_{g}, can be joined to form a ring. Obviously, it is also possible that none of these substituents are joined to form a ring.

According to an embodiment of the present disclosure, the ligand Lₐ is selected from a structure represented by Formula 4-2 or Formula 4-7.

According to an embodiment of the present disclosure, the ring G, the ring H, and the ring I are, at each occurrence identically or differently, selected from an aromatic ring having 6 to 18 carbon atoms or a heteroaromatic ring having 3 to 18 carbon atoms.

According to an embodiment of the present disclosure, the ring G, the ring H, and the ring I are, at each occurrence identically or differently, selected from a benzene ring, a naphthalene ring, a pyridine ring, a pyrimidine ring, a pyrazine ring, an azanaphthalene ring, a furan ring, a thiophene ring, an isoxazole ring, an isothiazole ring, a pyrrole ring, a pyrazole ring, a benzofuran ring, a benzothiophene ring, an azabenzofuran ring, or an azabenzothiophene ring.

According to an embodiment of the present disclosure, the ring G, the ring H, and the ring I are, at each occurrence identically or differently, selected from a benzene ring, a naphthalene ring, a pyridine ring, or a pyrimidine ring.

According to an embodiment of the present disclosure, the ligand Lₐ is, at each occurrence, selected from the group consisting of the following structures:

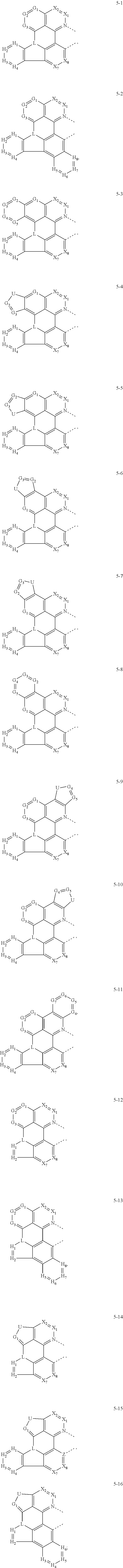

wherein
L is, at each occurrence identically or differently, selected from B, N, or P;
X₁, X₂, X₇, and X_{g} are, at each occurrence identically or differently, selected from N or CRₓ;
G₁ to G₇ are, at each occurrence identically or differently, selected from CR_{g} or N;
H₁ to H₈ are, at each occurrence identically or differently, selected from CRₕ or N;
U is, at each occurrence identically or differently, selected from O, S, Se, CRᵤRᵤ, SiRᵤRᵤ, PRᵤ, or NRᵤ; when two Rᵤ are present at the same time, the two Rᵤ are the same or different;
Rₓ, R_{g}, Rₕ, and Rᵤ, are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₓ, R_{g}, Rₕ, and Rᵤ can be optionally joined to form a ring.

In this embodiment, the expression that “adjacent substituents Rₓ, R_{g}, Rₕ, and Rᵤ can be optionally joined to form a ring” is intended to mean that any one or more of groups of adjacent substituents, such as two substituents Rₓ, two substituents R_{g}, two substituents Rₕ, two substituents Rᵤ, adjacent substituents Rᵤ and Rₓ, and adjacent substituents Rᵤ and R_{g}, can be joined to form a ring. Obviously, it is also possible that none of these substituents are joined to form a ring.

According to an embodiment of the present disclosure, the ligand Lₐ is selected from a structure represented by Formula 5-1, Formula 5-2, Formula 5-6, Formula 5-7, Formula 5-8, or Formula 5-11.

According to an embodiment of the present disclosure, the ligand Lₐ is selected from a structure represented by Formula 5-1, Formula 5-2, or Formula 5-11.

According to an embodiment of the present disclosure, the ligands L_{b} and Lₑ are, at each occurrence identically or differently, selected from the group consisting of Formula a to Formula m:

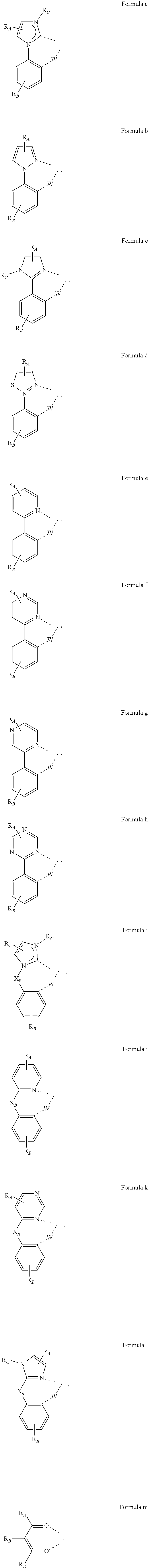

wherein
R_{A} and R_{B} represent, at each occurrence identically or differently, mono-substitution, multiple substitutions, or non-substitution;
X_{B} is, at each occurrence identically or differently, selected from the group consisting of: O, S, Se, NR_{N1}, and CR_{C1}R_{C2};
W is, at each occurrence identically or differently, selected from the group consisting of: a single bond, O, S, and Se;
R_{A}, R_{B}, R_{C}, R_{D}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, R_{D}, R_{N1}, R_{C1}, and R_{C2} can be optionally joined to form a ring.

In this embodiment, the expression that “adjacent substituents R_{A}, R_{B}, R_{C}, R_{D}, R_{N1}, R_{C1}, and R_{C2} can be optionally joined to form a ring” is intended to mean that any one or more of groups of adjacent substituents, such as two substituents R_{A}, two substituents R_{B}, two substituents R_{C}, substituents R_{A} and R_{B}, substituents R_{A} and R_{C}, substituents R_{B} and R_{C}, substituents R_{A} and R_{N1}, substituents R_{B} and R_{N1}, substituents R_{A} and R_{C1}, substituents R_{A} and R_{C2}, substituents R_{B} and R_{C1}, substituents R_{B} and R_{C2}, and substituents R_{C1} and R_{C2}, can be joined to form a ring. Obviously, it is also possible that none of these substituents are joined to form a ring.

According to an embodiment of the present disclosure, the metal complex has a structure represented by one of Formula 6 to Formula 11:

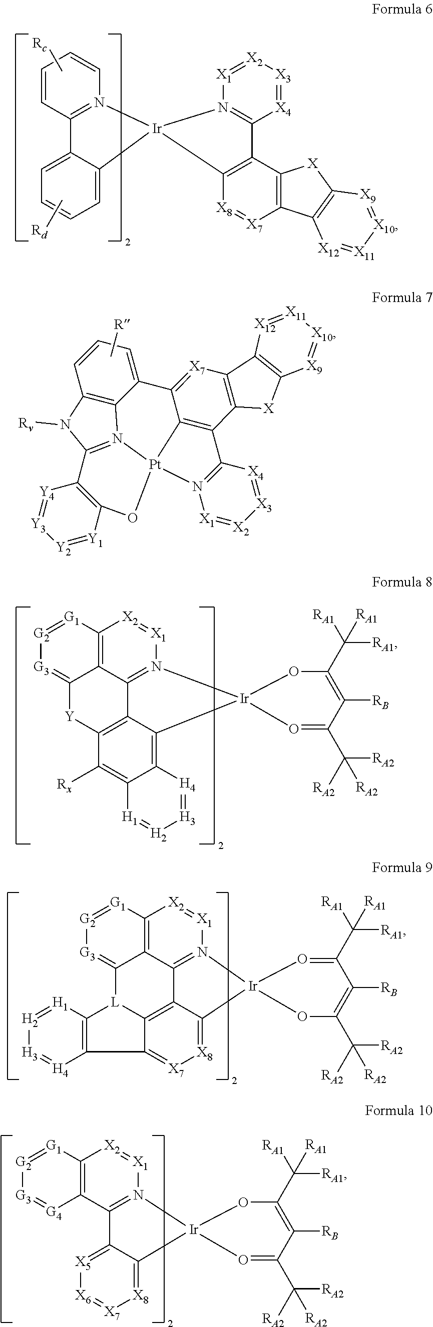

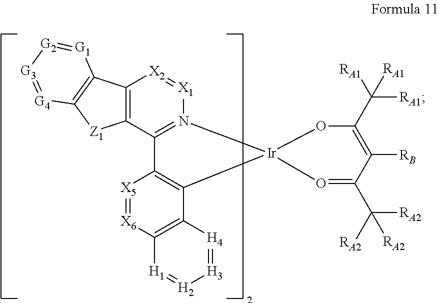

wherein
Z₁ and X are selected from the group consisting of O, S, Se, NR₂, CR₂R₂, and SiR₂R₂;
X₁ to X₁₂ are, at each occurrence identically or differently, selected from CRₓ or N;
Y₁ to Y₄ are, at each occurrence identically or differently, selected from CR_{y} or N;
Y is selected from SiR₃R₃, GeR₃R₃, NR₃, PR₃, O, S, or Se; when two R₃ are present at the same time, the two R₃ may be the same or different;
L is, at each occurrence identically or differently, selected from B, N, or P;
G₁ to G₄ are, at each occurrence identically or differently, selected from CR_{g} or N;
H₁ to H₄ are, at each occurrence identically or differently, selected from CRₕ or N;
R″, R_{c}, and R_{d} represent, at each occurrence identically or differently, mono-substitution, multiple substitutions, or non-substitution;
R_{A1}, R_{A2}, R_{B}, R₂, R₃, Rₓ, R_{y}, R″, R_{c}, R_{d}, R_{g}, Rₕ, and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
in Formula 6, adjacent substituents can be optionally joined to form a ring;
in Formula 7, adjacent substituents can be optionally joined to form a ring;
in Formula 8, adjacent substituents can be optionally joined to form a ring;
in Formula 9, adjacent substituents can be optionally joined to form a ring;
in Formula 10, adjacent substituents can be optionally joined to form a ring; and
in Formula 11, adjacent substituents can be optionally joined to form a ring.

In this embodiment, the expression that “in Formula 6, adjacent substituents can be optionally joined to form a ring” is intended to mean that any one or more of groups of adjacent substituents in Formula 6, such as two substituents Rₓ, two substituents R_{c}, two substituents R_{d}, adjacent substituents Rₑ and R_{d}, and adjacent substituents R₂ and Rₓ, can be joined to form a ring. Obviously, it is also possible that none of these substituents are joined to form a ring.

In this embodiment, the expression that “in Formula 7, adjacent substituents can be optionally joined to form a ring” is intended to mean that any one or more of groups of adjacent substituents in Formula 7, such as two substituents Rₓ, two substituents R_{y}, two substituents R″, and adjacent substituents Rᵥ and R″, can be joined to form a ring. Obviously, it is also possible that none of these substituents are joined to form a ring.

In this embodiment, the expression that “in Formula 8, adjacent substituents can be optionally joined to form a ring” is intended to mean that any one or more of groups of adjacent substituents in Formula 8, such as two substituents Rₓ, two substituents R_{g}, two substituents Rₕ, two substituents R₃, two substituents R_{A1}, two substituents R_{A2}, adjacent substituents R_{g} and R₃, adjacent substituents Rₓ and Rₕ, adjacent substituents Rₓ and R_{g}, adjacent substituents R_{B} and R_{A1}, and adjacent substituents R_{B} and R_{A2}, can be joined to form a ring. Obviously, it is also possible that none of these substituents are joined to form a ring.

In this embodiment, the expression that “in Formula 9, adjacent substituents can be optionally joined to form a ring” is intended to mean that any one or more of groups of adjacent substituents in Formula 9, such as two substituents Rₓ, two substituents R_{g}, two substituents Rₕ, two substituents R_{A1}, two substituents R_{A2}, adjacent substituents Rₓ and R_{g}, adjacent substituents R_{B} and R_{A1}, and adjacent substituents R_{B} and R_{A2}, can be joined to form a ring. Obviously, it is also possible that none of these substituents are joined to form a ring.

In this embodiment, the expression that “in Formula 10, adjacent substituents can be optionally joined to form a ring” is intended to mean that any one or more of groups of adjacent substituents in Formula 10, such as two substituents Rₓ, two substituents R_{g}, two substituents R_{A1}, two substituents R_{A2}, adjacent substituents Rₓ and R_{g}, adjacent substituents R_{B} and R_{A1}, and adjacent substituents R_{B} and R_{A2}, can be joined to form a ring. Obviously, it is also possible that none of these substituents are joined to form a ring.

In this embodiment, the expression that “in Formula 11, adjacent substituents can be optionally joined to form a ring” is intended to mean that any one or more of groups of adjacent substituents in Formula 11, such as two substituents Rₓ, two substituents Rₕ, two substituents R_{g}, two substituents R₂, two substituents R_{A1}, two substituents R_{A2}, adjacent substituents Rₓ and R_{g}, adjacent substituents R_{B} and R_{A1}, adjacent substituents R_{B} and R_{A2}, adjacent substituents R₂ and Rₓ, adjacent substituents R_{g} and R₂, adjacent substituents R_{g} and Rₓ, and adjacent substituents Rₕ and Rₓ, can be joined to form a ring. Obviously, it is also possible that none of these substituents are joined to form a ring.

According to an embodiment of the present disclosure, Z₁ is, at each occurrence identically or differently, selected from O or S.

According to an embodiment of the present disclosure, X is, at each occurrence identically or differently, selected from O or S.

According to an embodiment of the present disclosure, Y is, at each occurrence identically or differently, selected from O or S.

According to an embodiment of the present disclosure, Z₁ is, at each occurrence identically or differently, selected from S.

According to an embodiment of the present disclosure, X is O.

According to an embodiment of the present disclosure, Y is O.

According to an embodiment of the present disclosure, R_{A1}, R_{A2}, R_{B}, R₂, R₃, Rₓ, R_{y}, R″, R_{c}, R_{d}, R_{g}, Rₕ, and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, at least one of X₁ to X₁₂ is selected from CRₓ, and Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, cyano, and combinations thereof.

According to an embodiment of the present disclosure, at least one of X₉ to X₁₂ is selected from CRₓ, and Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one of X₉ to X₁₂ is selected from CRₓ, and Rₓ is, at each occurrence identically or differently, selected from substituted or unsubstituted aryl having 6 to 30 carbon atoms, substituted or unsubstituted heteroaryl having 3 to 30 carbon atoms, cyano, or a combination thereof.

According to an embodiment of the present disclosure, at least one of X₉ to X₁₂ is selected from CRₓ, and Rₓ is cyano.

According to an embodiment of the present disclosure, X₁₀ is selected from CRₓ, and Rₓ is cyano.

According to an embodiment of the present disclosure, at least two of X₉ to X₁₂ are selected from CRₓ, and Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least two of X₉ to X₁₂ are selected from CRₓ, and Rₓ is, at each occurrence identically or differently, selected from the group consisting of: substituted or unsubstituted aryl having 6 to 30 carbon atoms, substituted or unsubstituted heteroaryl having 3 to 30 carbon atoms, cyano, and combinations thereof.

According to an embodiment of the present disclosure, at least two of X₉ to X₁₂ are selected from CRₓ, one Rₓ is cyano, and at least one Rₓ is substituted or unsubstituted aryl having 6 to 30 carbon atoms or substituted or unsubstituted heteroaryl having 3 to 30 carbon atoms.

According to an embodiment of the present disclosure, X₁₀ is selected from CRₓ, and Rₓ is cyano; X₉ is selected from CRₓ, and Rₓ is substituted or unsubstituted aryl having 6 to 30 carbon atoms or substituted or unsubstituted heteroaryl having 3 to 30 carbon atoms.

According to an embodiment of the present disclosure, X₉ to X₁₂ are, at each occurrence identically or differently, selected from N or CRₓ, and Rₓ and Rₓ are not joined to form a ring.

According to an embodiment of the present disclosure, X₉ to X₁₂ are, at each occurrence identically or differently, selected from N or CRₓ, and Rₓ and Rₓ are joined to form a five-membered ring.

According to an embodiment of the present disclosure, at least one or at least two of Rₑ are selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, at least one or at least two of R_{d} are selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, at least one or at least two of Rₑ are selected from substituted or unsubstituted alkyl having 1 to 20 carbon atoms, substituted or unsubstituted cycloalkyl having 3 to 20 ring carbon atoms, or a combination thereof, and the total number of carbon atoms in all of Rₑ is at least 4.

According to an embodiment of the present disclosure, at least one or at least two of R_{d} are selected from substituted or unsubstituted alkyl having 1 to 20 carbon atoms, substituted or unsubstituted cycloalkyl having 3 to 20 ring carbon atoms, or a combination thereof, and the total number of carbon atoms in all of R_{d} is at least 4.

According to an embodiment of the present disclosure, W is, at each occurrence identically or differently, selected from a single bond, O, or S.

According to an embodiment of the present disclosure, W is, at each occurrence identically or differently, selected from a single bond or O.

According to an embodiment of the present disclosure, Rₓ, R_{y}, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, X₁ to X₈ are, at each occurrence identically or differently, selected from CRₓ; G₁ to G₄ are, at each occurrence identically or differently, selected from CR_{g}; H₁ to H₄ are, at each occurrence identically or differently, selected from CRₕ; and Rₓ, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, X₁ to X₈ are, at each occurrence identically or differently, selected from CRₓ; G₁ to G₃ are, at each occurrence identically or differently, selected from CR_{g}; H₁ to H₄ are, at each occurrence identically or differently, selected from CRₕ; and at least two or three of Rₓ, R_{g}, and Rₕ are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, in Formula 8 and Formula 9, G₂ is CR_{g} and/or H₃ is CRₕ and/or X₈ is CRₓ, and R_{g}, Rₕ, and Rₓ, are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, in Formula 2-1 and Formula 10, X₅ to X₈ are, at each occurrence identically or differently, selected from CRₓ.

According to an embodiment of the present disclosure, in Formula 2-1 and Formula 10, X₆ and/or X₈ are, at each occurrence identically or differently, selected from CRₓ, and Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and substituted or unsubstituted alkylsilyl having 3 to 20 carbon atoms.

According to an embodiment of the present disclosure, in Formula 2-1 and Formula 10, X₅ and X₇ are CH, X₆ and/or X₈ are, at each occurrence identically or differently, selected from CRₓ, and Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and substituted or unsubstituted alkylsilyl having 3 to 20 carbon atoms.

According to an embodiment of the present disclosure, in Formula 2-1 and Formula 10, G₁ to G₄ are, at each occurrence identically or differently, selected from CR_{g}.

According to an embodiment of the present disclosure, in Formula 2-1 and Formula 10, G₂ is CR_{g}, and R_{g} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof.

According to an embodiment of the present disclosure, in Formula 2-1 and Formula 10, G₂ is CR_{g}, and R_{g} is, at each occurrence identically or differently, selected from substituted or unsubstituted alkyl having 1 to 20 carbon atoms, substituted or unsubstituted cycloalkyl having 3 to 20 ring carbon atoms, or substituted or unsubstituted alkylsilyl having 3 to 20 carbon atoms; and G₁, G₃, and G₄ are each CH.

According to an embodiment of the present disclosure, in Formula 2-2 and Formula 11, Z₁ is selected from O or S.

According to an embodiment of the present disclosure, in Formula 2-2 and Formula 11, X₁, X₂, X₅, and X₆ are, at each occurrence identically or differently, selected from CRₓ; G₁ to G₄ are, at each occurrence identically or differently, selected from CR_{g}; H₁ to H₄ are, at each occurrence identically or differently, selected from CRₕ; and Rₓ, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, in Formula 2-2 and Formula 11, X₆ is, at each occurrence identically or differently, selected from CRₓ; G₄ is, at each occurrence identically or differently, selected from CR_{g}; and Rₓ and R_{g} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, in Formula 8 to Formula 11, at least one or two of R_{A1} are selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof.

According to an embodiment of the present disclosure, in Formula 8 to Formula 11, at least one or two of R_{A2} are selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof.

According to an embodiment of the present disclosure, in Formula 8 to Formula 11, at least two of R_{A1} are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

According to an embodiment of the present disclosure, in Formula 8 to Formula 11, at least two of R_{A2} are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

According to an embodiment of the present disclosure, the first light-emitting doped material is selected from a metal complex having a structure of Formula 6 or Formula 7.

According to an embodiment of the present disclosure, the first light-emitting doped material is, at each occurrence identically or differently, selected from the group consisting of Metal Complex 1 to Metal Complex 38, Compound 99, and Compound 100, wherein Metal Complex 1 to Metal Complex 38, Compound 99, and Compound 100 have the following specific structures:

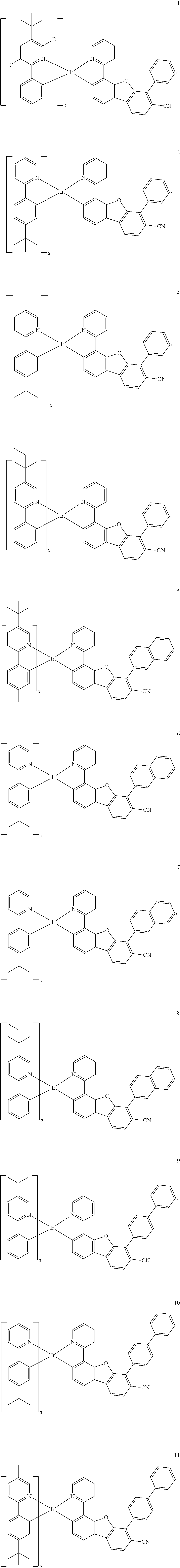

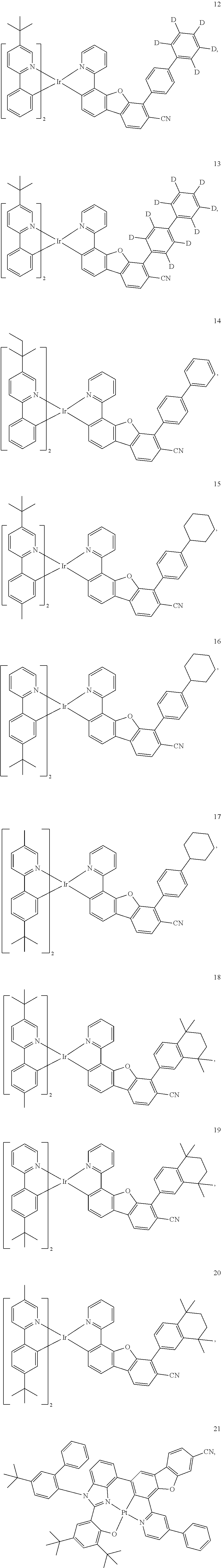

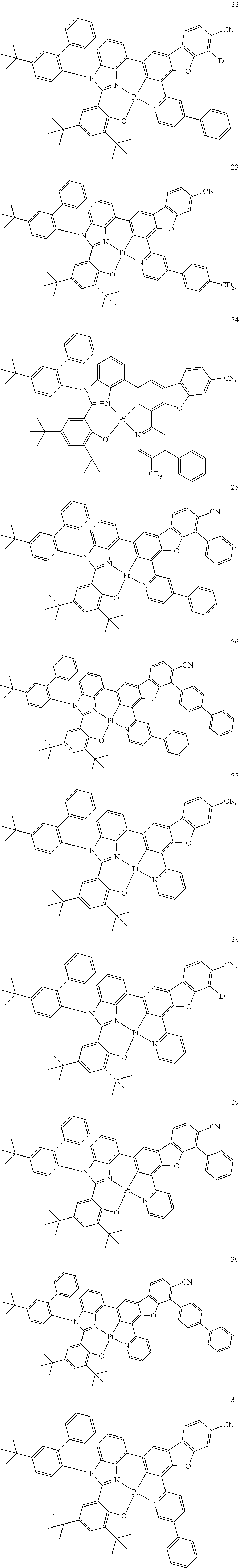

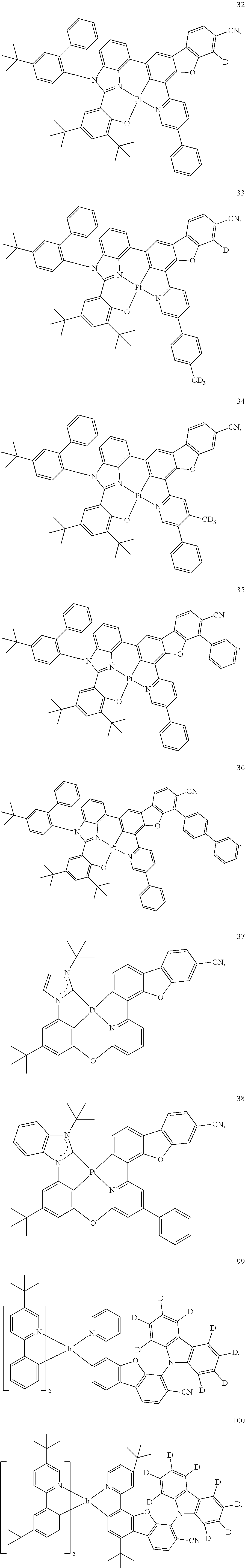

According to an embodiment of the present disclosure, the second light-emitting doped material is selected from a metal complex having a structure represented by any one of Formula 8 to Formula 11.

According to an embodiment of the present disclosure, the second light-emitting doped material is, at each occurrence identically or differently, selected from the group consisting of Metal Complex 39 to Metal Complex 98 and Metal Complex 101 to Metal Complex 132, wherein Metal Complex 39 to Metal Complex 98 and Metal Complex 101 to Metal Complex 132 have the following specific structures:

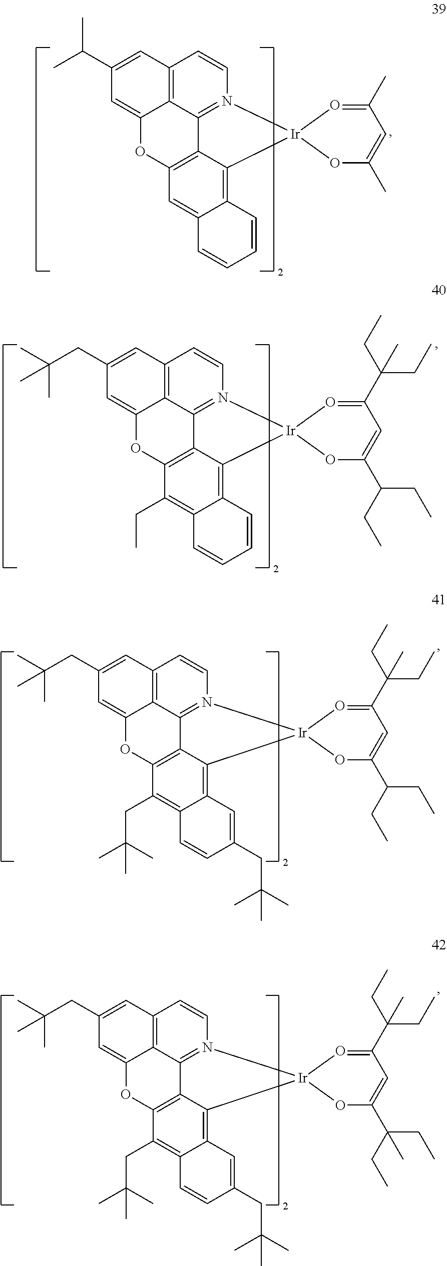

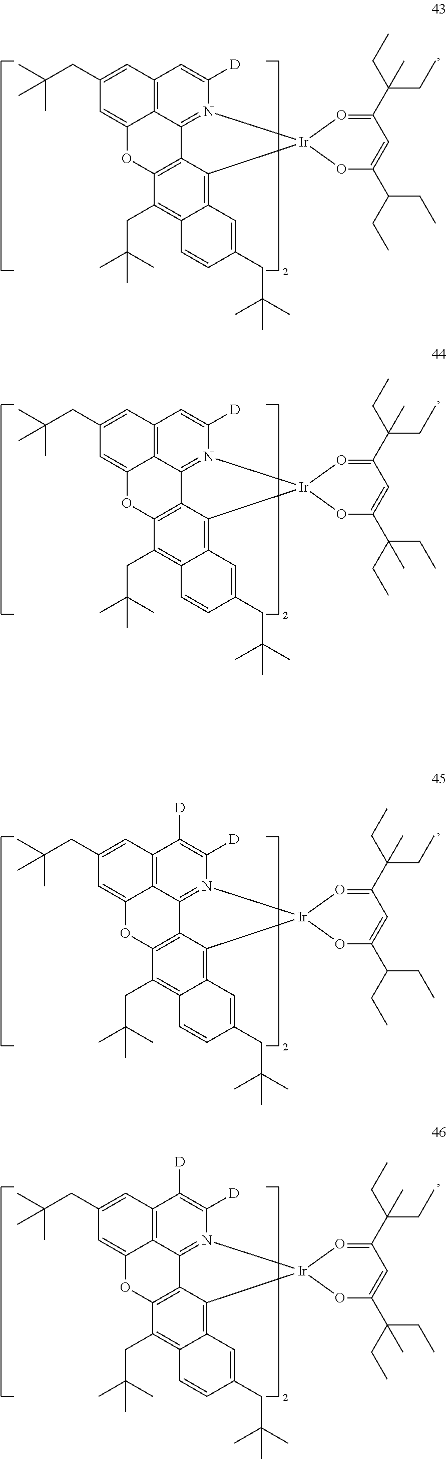

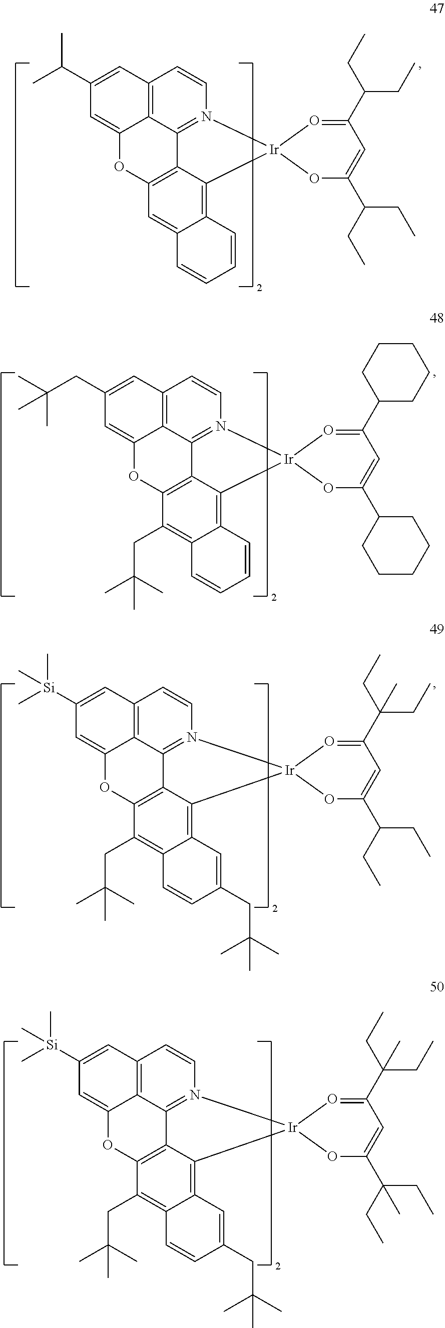

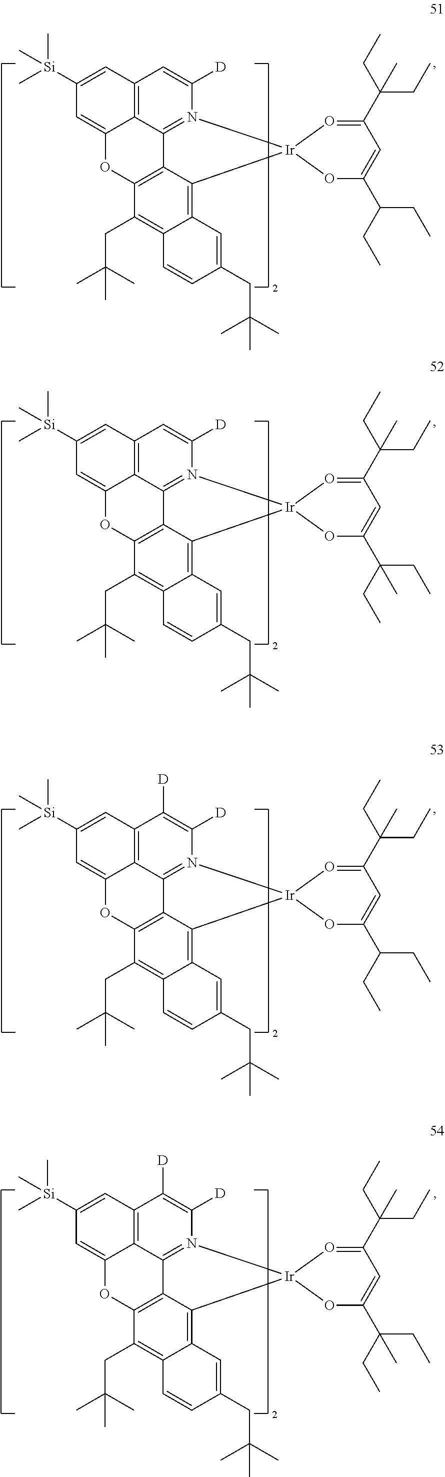

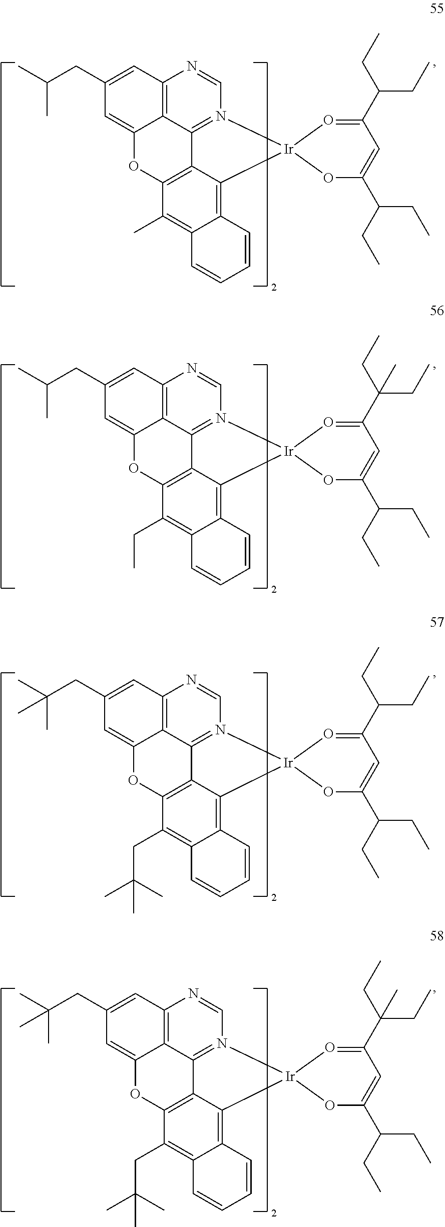

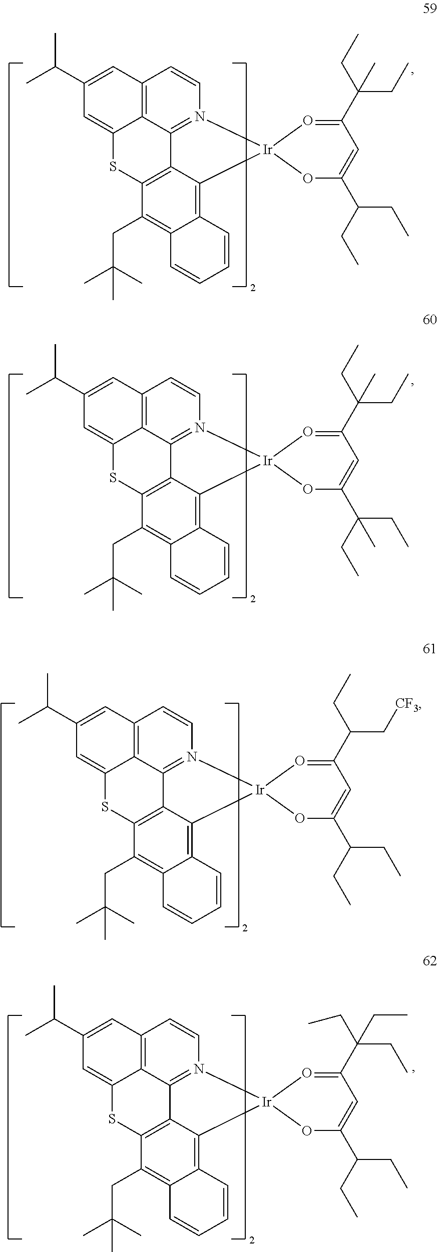

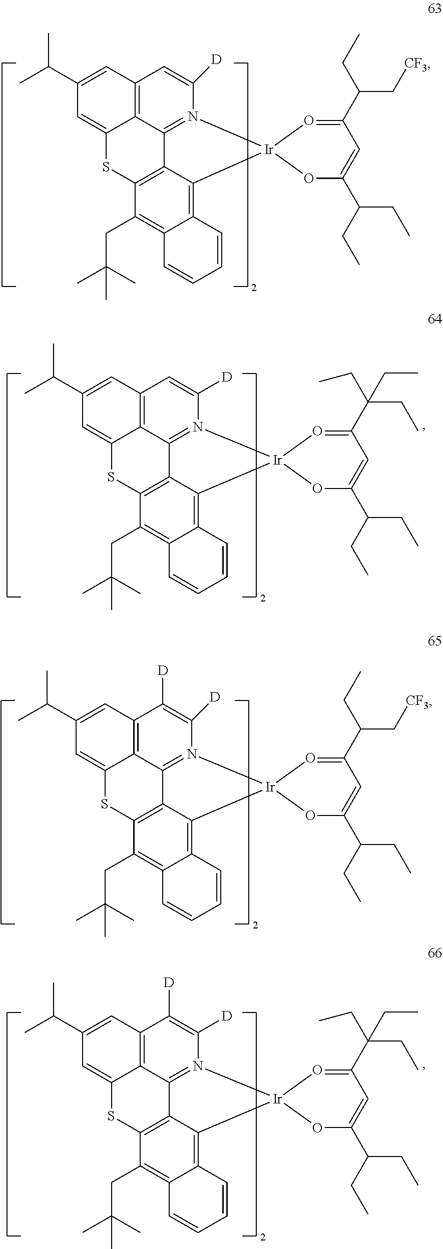

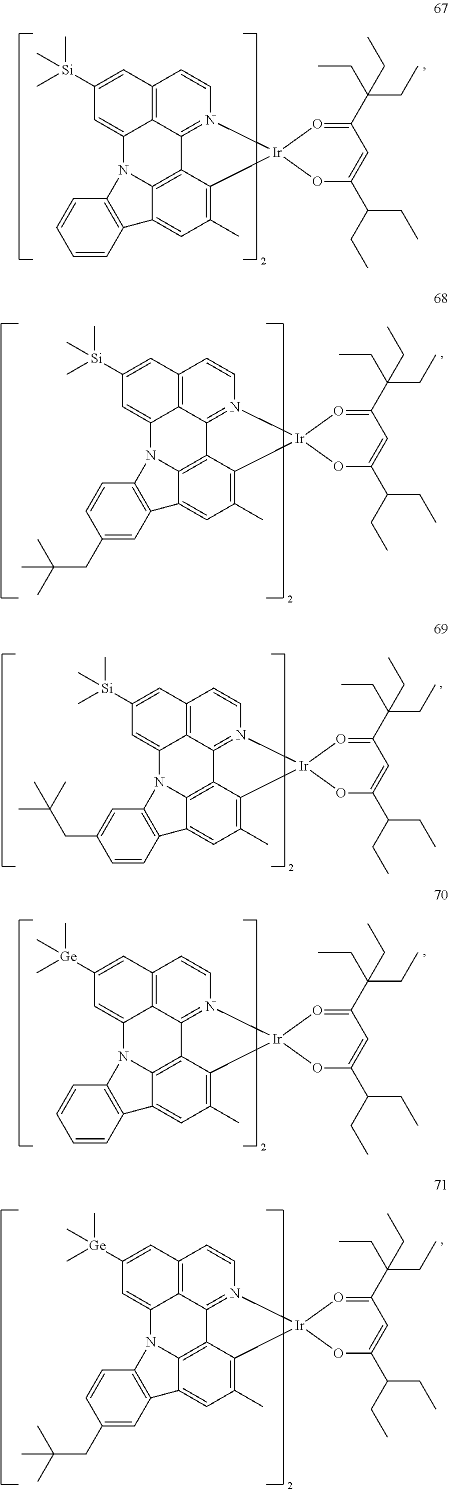

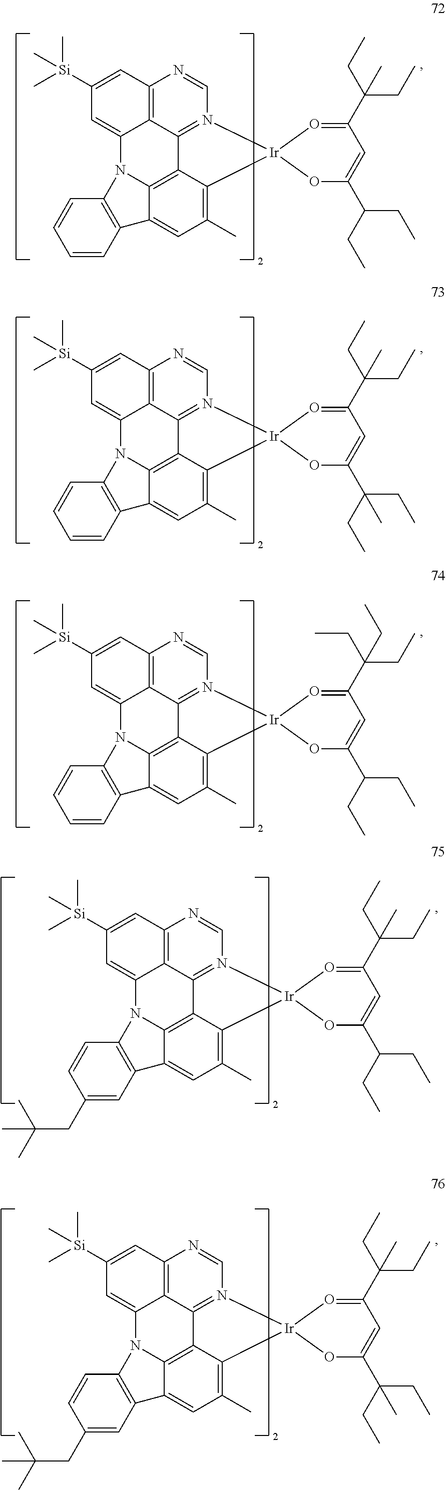

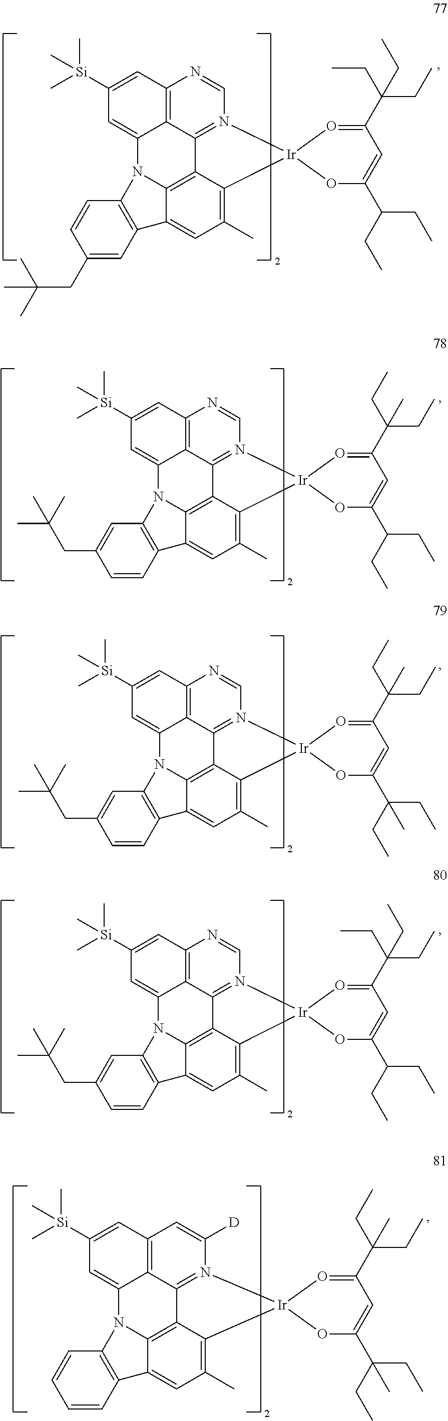

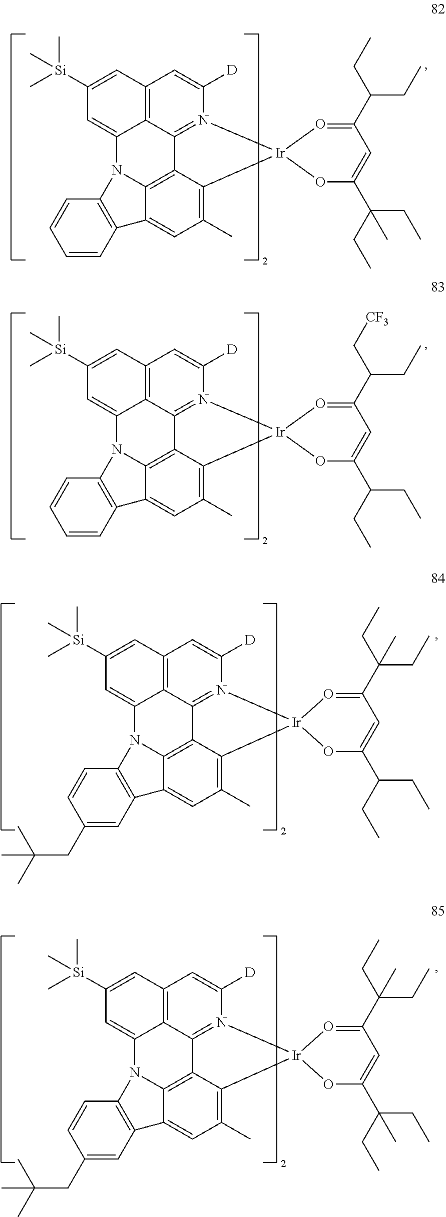

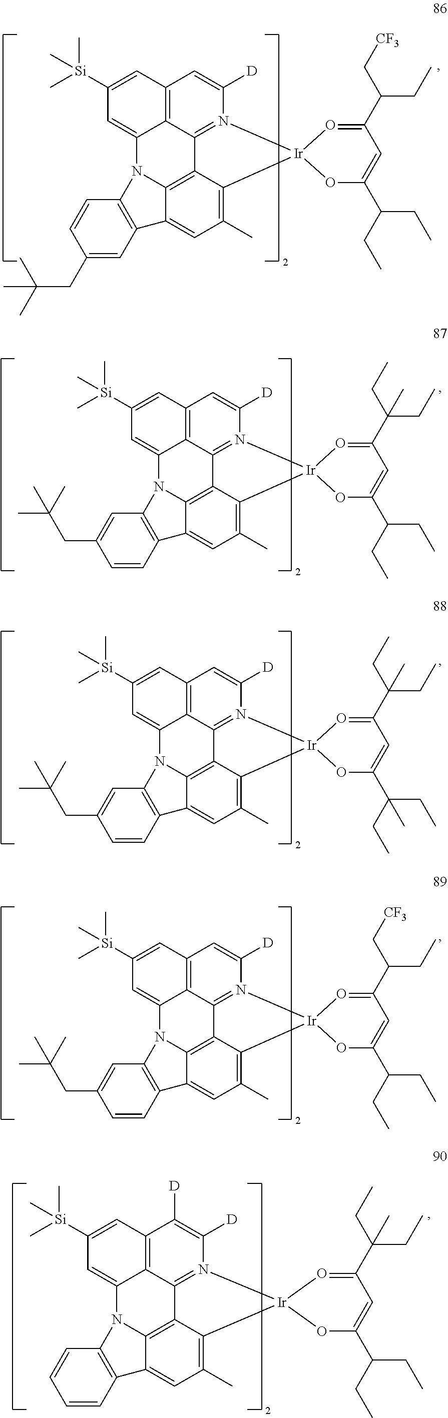

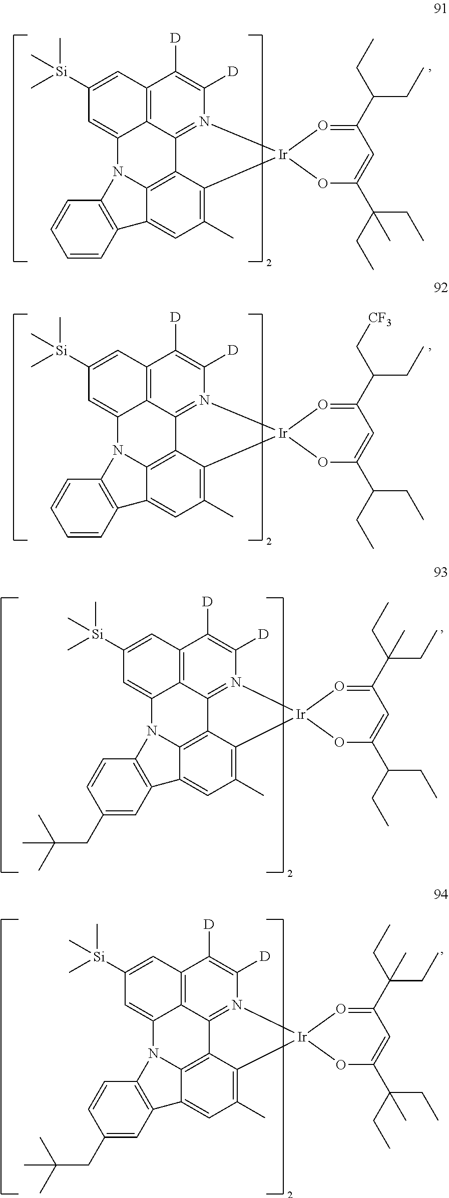

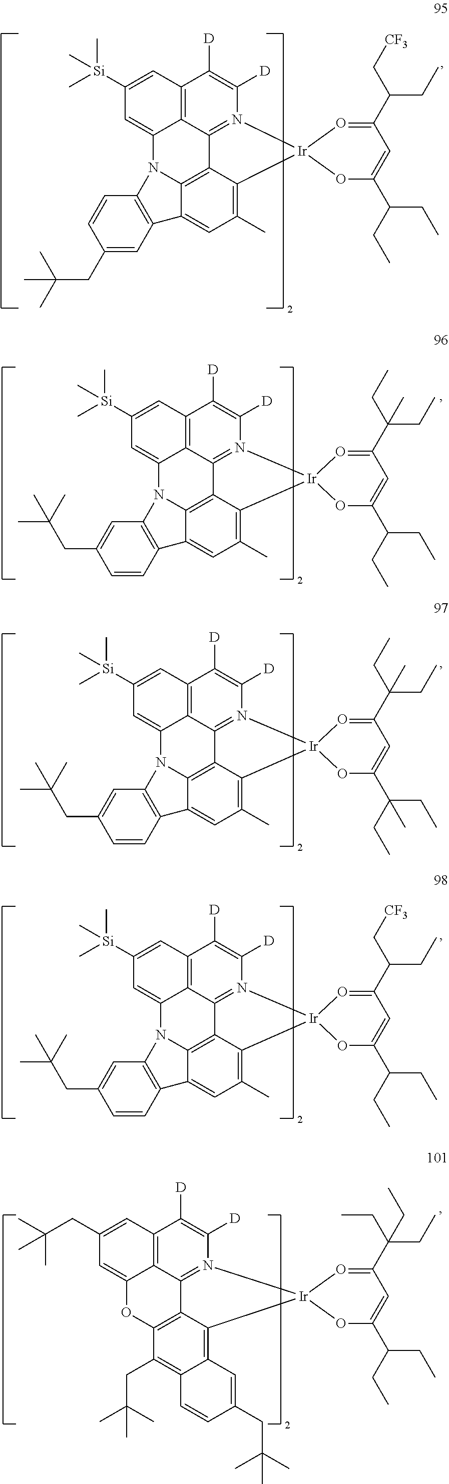

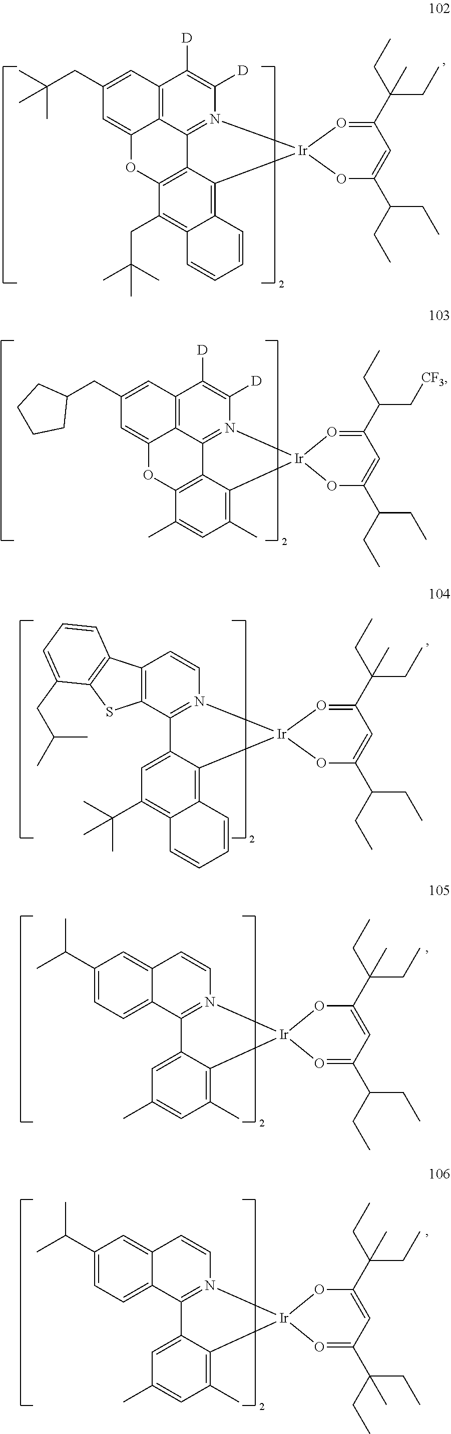

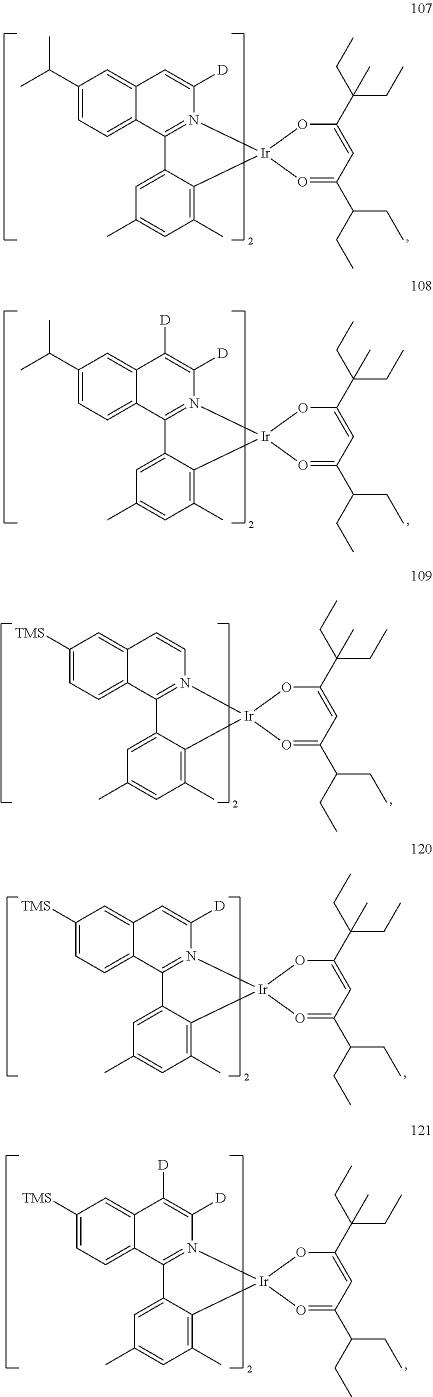

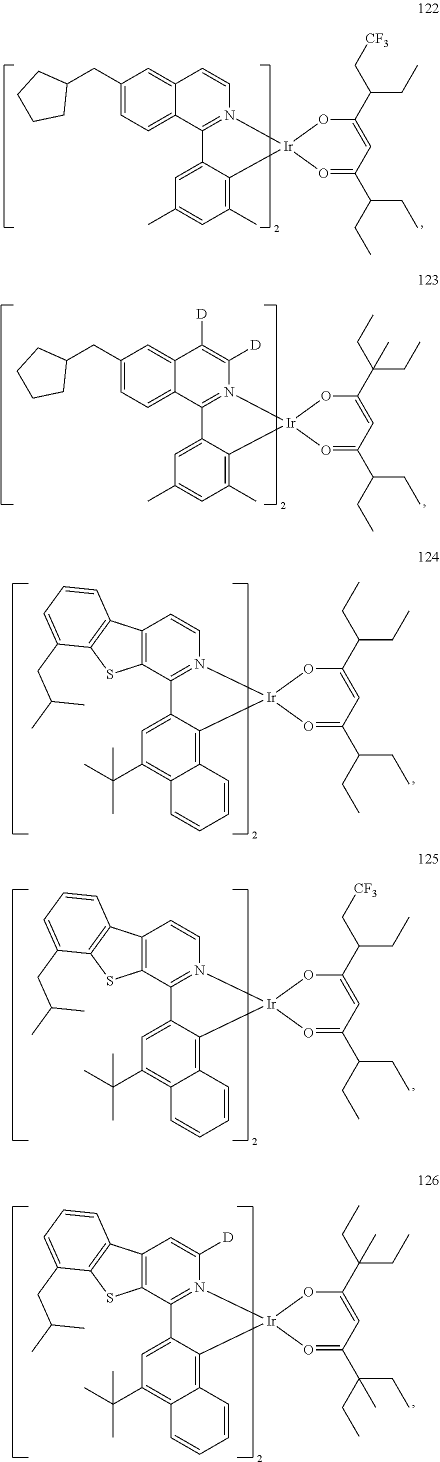

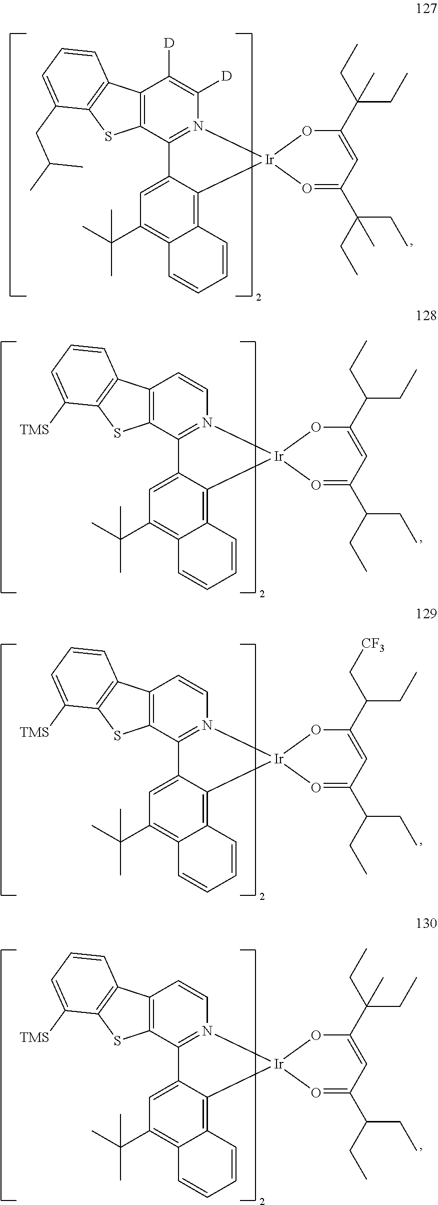

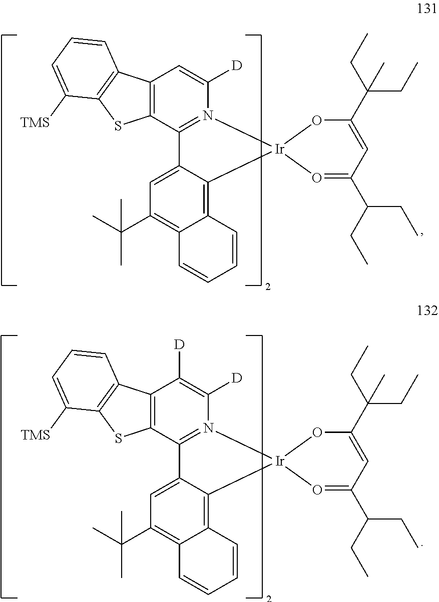

According to an embodiment of the present disclosure, each of the first light-emitting layer, the second light-emitting layer, and the third light-emitting layer further comprises at least one host compound.

According to an embodiment of the present disclosure, each of the first light-emitting layer, the second light-emitting layer, and the third light-emitting layer comprises at least two host compounds.

According to an embodiment of the present disclosure, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, further disclosed is an electronic assembly comprising the organic electroluminescent display panel in any one of the preceding embodiments.

To solve the problem of a color cast of an organic electroluminescent display panel due to inconsistent luminance decay tendencies of red and green top-emitting OLED devices at various angles, a match of red and green light-emitting materials whose full widths at half maximum of PL spectra have a difference within a particular range is studied and selected in the present disclosure to be applied to red and green light devices of the display panel, ensuring that the luminance decay degrees of red light and green light of the display panel are basically the same at a different viewing angle and improving the color cast of the panel.

As is known to us, a full width at half maximum and a shoulder strength of a spectrum are important parameters of the spectrum of a phosphorescent material. To study the effects of these parameters on a luminance decay, a series of simulation experiments were conducted.

FIG. 3a shows a series of red light spectra (S1-100, S1-80, S1-60, S1-40, and S1-20) with different shoulder strengths and a series of red light spectra (S2-1, S2-2, and S2-3) with different FWHMs, separately. A spectrum S1-100 had a maximum emission wavelength (λₘₐₓ) of 622 nm and an FWHM of 35 nm; and the shoulder strength of the spectrum S1-100 was compressed to 80%, 60%, 40%, and 20% for S1-80, S1-60, S1-40, and S1-20 respectively to obtain a series of spectra. Spectra S2-1, S2-2, and S2-3 all have a maximum emission wavelength (λₘₐₓ) of 622 nm and have an FWHM of 30 nm, 40 nm, and 49 nm, respectively. The spectrum data of S1-100, S1-80, S1-60, S1-40, S1-20, and S2-1 to S2-3 were substituted into the top-emitting structure shown in FIG. 2a, separately, and optical simulation was performed by the preceding method through Setfos 5.1.1 semiconductor thin-film optical simulation software developed by FLUXiM. Table 1 lists the luminance decay data obtained through the simulation.

TABLE 1
Luminance decay data of devices corresponding to red light spectra
S1-20 to S1-100 and S2-1 to S2-3 and obtained through simulation

| | | | | Normalized | | | Corresponding |
|---|---|---|---|---|---|---|---|
| | | | | Integral Area | Corresponding | Corresponding | Luminance |
| Spectrum | λmax | FWHM | Shoulder | A of the | Luminance | Luminance | Decay at 30° |
| No. | [nm] | [nm] | Strength | Spectrum | L0 at 0° | L30 at 30° | D = L30/L0 |
| S1-100 | 622 | 35 | 100% | 47.8 | 6530 | 3570 | 54.7% |
| S1-80 | 622 | 35 | 80% | 44.9 | 6930 | 3790 | 54.7% |
| S1-60 | 622 | 35 | 60% | 41.9 | 7410 | 4040 | 54.5% |
| S1-40 | 622 | 35 | 40% | 38.8 | 7990 | 4360 | 54.6% |
| S1-20 | 622 | 35 | 20% | 35.6 | 8710 | 4740 | 54.4% |
| S2-1 | 622 | 30 | 100% | 41.1 | 6864 | 3478 | 50.7% |
| S2-2 | 622 | 40 | 100% | 54.4 | 6232 | 3836 | 61.6% |
| S2-3 | 622 | 49 | 100% | 66.4 | 5769 | 3793 | 65.8% |

As can be known from the data in Table 1, the corresponding luminance decay values D of the devices using the spectra S1-100 to S1-20 in an EML at a viewing angle of 30° were maintained between 54.7% and 54.4%. The spectra S1-100 to S1-20 only changed in shoulder strength. It can be seen that in the case where the FWHM remained unchanged, a change in the shoulder strength of the red light spectrum basically had no effect on the luminance decay value. Therefore, when effects on the luminance decay value of red light were considered, only an effect of the FWHM was considered, and the effect of the shoulder strength may be ignored.

The FWHM of the spectrum S2-1 was 30 nm, which was 5 nm narrower than those of S1-100 to S1-20. It can be seen that the corresponding luminance decay value D at the viewing angle of 30° was reduced to 50.7%. This indicates that the narrower the FWHM, the smaller the luminance decay value D, that is, the greater the luminance decay as the viewing angle changes. The FWHMs of the spectra S2-2 and S2-3 were 40 nm and 49 nm, respectively, which were 5 nm and 14 nm wider than those of S1-100 to S1-20, respectively. It can be seen that the corresponding luminance decay values D at 30° were increased to 61.6% and 65.8%, respectively. This indicates that the wider the FWHM, the larger the luminance decay value D, that is, the smaller the luminance decay as the viewing angle changes.

Further, effects of a shoulder and an integral area of a green light spectrum on the luminance decay of the device were also studied.

FIG. 3b shows a series of green light spectra (S3-100, S3-80, S3-60, S3-40, and S3-20) with different shoulder strengths and a series of green light spectra (S4-1, S4-2, and S4-3) with different FWHMs. A spectrum S3-100 had a maximum emission wavelength (λₘₐₓ) of 532 nm and an FWHM of 35 nm; and the shoulder strength of the spectrum S3-100 was compressed to 80%, 60%, 40%, and 20% for S3-80, S3-60, S3-40, and S3-20 respectively to obtain a series of spectra. Spectra S4-1, S4-2, and S4-3 all have a maximum emission wavelength (λₘₐₓ) of 532 nm and have an FWHM of 30 nm, 40 nm, and 49 nm, respectively. The spectrum data of S3-100, S3-80, S3-60, S3-40, S3-20 and S4-1 to S4-3 were substituted into the top-emitting structure shown in FIG. 2a, separately, and optical simulation was performed by the preceding method through Setfos 5.1.1 semiconductor thin-film optical simulation software developed by FLUXiM. Table 2 lists the luminance decay data obtained through the simulation.

TABLE 2
Luminance decay data of devices corresponding to green light spectra
S3-20 to S3-100 and S4-1 to S4-3 and obtained through simulation

| | | | | Normalized | | | Corresponding |
|---|---|---|---|---|---|---|---|
| | | | | Integral Area | Corresponding | Corresponding | Luminance |
| Spectrum | λmax | FWHM | Shoulder | A of the | Luminance | Luminance | Decay at 30° |
| No. | [nm] | [nm] | Strength | Spectrum | L0 at 0° | L30 at 30° | D = L30/L0 |
| S3-100 | 532 | 35 | 100% | 47.8 | 2432 | 1722 | 70.8% |
| S3-80 | 532 | 35 | 80% | 44.9 | 2121 | 1501 | 70.8% |
| S3-60 | 532 | 35 | 60% | 41.9 | 1747 | 1237 | 70.8% |
| S3-40 | 532 | 35 | 40% | 38.8 | 1292 | 915 | 70.9% |
| S3-20 | 532 | 35 | 20% | 35.6 | 727 | 516 | 71.0% |
| S4-1 | 532 | 30 | 100% | 41.1 | 2153 | 1413 | 65.7% |
| S4-2 | 532 | 40 | 100% | 54.4 | 2532 | 1812 | 71.6% |
| S4-3 | 532 | 49 | 100% | 66.4 | 2455 | 1869 | 76.1% |

As can be known from the data in Table 2, the corresponding luminance decay values D at the viewing angle of 30° were maintained between 70.8% to 71.0%, that is, in the case where the FWHM remained unchanged, changes in the shoulder strength and integral area of the green light spectrum basically had no effect on the luminance decay value. The FWHMs of the spectra S4-1 to S4-3 were 30 nm, 40 nm, and 49 nm, respectively. Like red light, the wider the FWHM, the greater the luminance decay value D, that is, the smaller the luminance decay as the viewing angle changes. Therefore, like the red light, when effects on the luminance decay value of green light were considered, only the effect of the FWHM was considered, and the effect of the shoulder strength may be ignored.

As can be known from the preceding simulation data, the FWHM of a light-emitting material has an extremely important effect on the luminance decay of the device, and the wider the FWHM, the smaller the luminance decay as the viewing angle changes. From the perspective of the viewing angle, this is what researchers in the display field expect. However, for two materials with the same EQE, when a material with the wider FWHM is prepared into a top-emitting device, the device efficiency of the top-emitting device is improved to a limited extent due to a microcavity effect compared with that of a bottom-emitting device, that is, the material with the wider FWHM has relatively low efficiency in the top-emitting device. Therefore, considering the device efficiency, a material with a narrow FWHM is expected by researchers in the art. To balance the efficiency and the viewing angle, in addition to the spectrum of a single material, a match of different colors (that is, different light-emitting materials) needs to be considered.

On this basis, decay degrees of light with different wavelengths at different viewing angles are further studied.

Specifically, the red light spectrum S1-100 (with an FWHM of 35 nm) was red-shifted or blue-shifted to different degrees to obtain a series of red light, green light, and blue light spectra listed in Table 3 (S5 to S10, as shown in FIG. 4a). Similarly, the spectrum data of the series were substituted into the top-emitting structure shown in FIG. 2a, and optical simulation was performed by the preceding method through Setfos 5.1.1 semiconductor thin-film optical simulation software developed by FLUXiM. FIG. 4b shows the luminance decay data of the spectra S5 to S10 at different viewing angles (within a range of 0° to 60°), which were obtained through simulation. Table 3 lists luminance changes and luminance decay data at different viewing angles (within the range of 0° to 30°), which were obtained through simulation.

TABLE 3
Luminance decay data of devices corresponding to spectra S5 to S10, at a
viewing angle of 0° to 30°, and obtained through simulation

| | | | Corre- | Corre- | Corre- |
|---|---|---|---|---|---|
| | | | sponding | sponding | sponding |
| | | | Luminance | Luminance | Luminance |
| Spectrum | λmax | FWHM | Decay D at | Decay D at | Decay D at |
| No. | [nm] | [nm] | 0° | 15° | 30° |
| S5 | 460 | 35 | 100% | 104.5% | 67.6% |
| S6 | 500 | 35 | 100% | 103.1% | 66.2% |
| S7 | 520 | 35 | 100% | 101.3% | 65.1% |
| S8 | 602 | 35 | 100% | 98.5% | 62.5% |
| S9 | 612 | 35 | 100% | 96.8% | 59.3% |
| S10 | 622 | 35 | 100% | 94.6% | 54.7% |

Since an angle most commonly used when a display device is used is about 30°, the corresponding luminance decay at the viewing angle of 30° was used as an indicator to be studied. As can be known from the data in FIG. 4b and Table 3, within a range of 0° to 60° of the viewing angle, the spectra S5 to S10 with the same FWHM have small luminance changes at a viewing angle of 0°, 45°, and 60° and have the largest changes at 15° and 30°. At the viewing angle of 30°, when the maximum emission wavelength was 460 nm, the luminance decay D was 67.6%; when the maximum emission wavelength was red-shifted to 520 nm, the luminance decay D was 65.1%; when the maximum emission wavelength was red-shifted to 622 nm, the luminance decay D was 54.7%. That is to say, in the case where the luminescence spectrum has the same waveform, the luminance decay of the spectrum in a red light band is more severe than that in a green light band, and the decays of the spectrum in the green light band and the red light band are more severe than that in a blue light band.

It is generally thought in the industry that when the luminance decay values D of different colors in the display panel differ within a range of 15%, the display panel can basically maintain the uniform luminance decay and has a relatively small color cast, and therefore a difference between the FWHMs of red light and green light is allowed to fluctuate within a certain range. On this basis, the present disclosure creatively proposes a new display panel. The PL spectra of red light and green light are controlled to satisfy some conditions (the FWHMs are within particular ranges, and the difference between the FWHMs satisfies a particular range; preferably, the difference between the FWHMs of red light and green light is greater than or equal to −15 nm) so that when the red light decays greatly, the green light decays to the similar extent, thereby reducing changes of a white balance at different viewing angles. In particular, the light-emitting material with a narrow FWHM is selected to ensure the efficiency and color purity of the device.

A series of simulations and device measurements were performed and the corresponding data were provided to prove the technical effects of the present disclosure.

### Simulation Example

### Simulation Example 1

(1) Simulation of a green pixel device: A green light spectrum S-520-30 was substituted into the top-emitting structure shown in FIG. 2a, and optical simulation was performed by the preceding method through Setfos 5.1.1 semiconductor thin-film optical simulation software developed by FLUXiM.

(2) Simulation of a red pixel device: A red light spectrum S-622-40 was substituted into the top-emitting structure shown in FIG. 2a, and optical simulation was performed by the preceding method through Setfos 5.1.1 semiconductor thin-film optical simulation software developed by FLUXiM.

### Simulation Example 2

Simulation Example 2 had the same method as Simulation Example 1 except that a green light spectrum S-520-35 was substituted in the simulation of the green pixel device, and a red light spectrum S-622-30 was substituted in the simulation of the red pixel device.

### Simulation Example 3

Simulation Example 3 had the same method as Simulation Example 1 except that a green light spectrum S-520-35 was substituted in the simulation of the green pixel device, and a red light spectrum S-622-40 was substituted in the simulation of the red pixel device.

### Simulation Example 4

Simulation Example 4 had the same method as Simulation Example 1 except that a green light spectrum S-520-40 was substituted in the simulation of the green pixel device, and a red light spectrum S-622-40 was substituted in the simulation of the red pixel device.

Graphs of the green light and red light spectra used in Simulation Examples 1 to 4 are shown in FIGS. 5a and 5b. The maximum emission wavelengths λ1 and λ2 [nm] and the FWHMs FWHM1 and FWHM2 corresponding to the green light and the red light and the difference between the FWHMs of the red light and green light spectra (ΔFWHM, ΔFWHM=FWHM2−FWHM1) are recorded and shown in Table 4.

TABLE 4
Parameters of the red light and green light
spectra used in Simulation Examples 1 to 4

| | Green Light Spectrum | | | Red Light Spectrum | | | ΔFWHM |
|---|---|---|---|---|---|---|---|
| Simulation | Spectrum | λ1 | FWHM1 | Spectrum | λ2 | FWHM2 | (FWHM2 − |
| Example No. | No. | [nm] | [nm] | No. | [nm] | [nm] | FWHM1) |
| Simulation | S-520-30 | 520 | 30 | S-622-40 | 622 | 40 | 10 |
| Example 1 | | | | | | | |
| Simulation | S-520-35 | 520 | 35 | S-622-30 | 622 | 30 | −5 |
| Example 2 | | | | | | | |
| Simulation | S-520-35 | 520 | 35 | S-622-40 | 622 | 40 | 5 |
| Example 3 | | | | | | | |
| Simulation | S-520-40 | 520 | 40 | S-622-40 | 622 | 40 | 0 |
| Example 4 | | | | | | | |

The preceding spectra were substituted, the luminance (L0) corresponding to the red and green pixel devices at a viewing angle of 0°, the luminance (L30) corresponding to the red and green pixel devices at a viewing angle of 30°, and the luminance decay values (D1, D1=L30/L0) corresponding to the red and green pixel devices at a viewing angle of 30° were obtained through simulation, and the luminance decay differences (ΔD, ΔD=D1−D32) of the green and red pixel devices were calculated. The preceding data are all shown in Table 5. Table 5 Luminance and luminance decay data of the red and green pixel devices in Simulation

Examples 1 to 4

| Simulation | Green Pixel Device | | | Red Pixel Device | | | ΔD |
|---|---|---|---|---|---|---|---|
| Example No. | L0 | L30 | D1 | L0 | L30 | D2 | (D1 − D2) |
| Simulation | 1298 | 847 | 65.2% | 6232 | 3836 | 61.6% | 3.6% |
| Example 1 | | | | | | | |
| Simulation | 1731 | 1129 | 65.2% | 6864 | 3478 | 50.7% | 14.5% |
| Example 2 | | | | | | | |
| Simulation | 1731 | 1129 | 65.2% | 6232 | 3836 | 61.6% | 3.6% |
| Example 3 | | | | | | | |
| Simulation | 2011 | 1428 | 71.0% | 6232 | 3836 | 61.6% | 9.4% |
| Example 4 | | | | | | | |

The data of the preceding simulation examples have shown that red light and green light materials whose FWHMs have a particular relationship (FWHM of red light−FWHM of green light≥−15 nm) are properly selected in the display panel so that the red and green devices have the consistent luminance decays to a certain extent, thereby satisfying a requirement of the industry on the color cast (D values differ within a range of 15%).

Moreover, a series of measured device data are further provided to specifically describe the working principle of a new organic light-emitting display panel of the present disclosure. Apparently, the following examples are only for the purpose of illustration and are not intended to limit the scope of the present disclosure. Based on the following examples, those skilled in the art can obtain other examples of the present disclosure by conducting improvements on these examples.

In device examples, the characteristics of a device are tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP) by methods well known to those skilled in the art. As those skilled in the art are aware of the above-mentioned equipment use, test methods, and other related contents, the inherent data of the sample can be obtained with certainty and without influence, so the above related contents are not further described in this patent.

### Device Example

Each of the following device examples and comparative examples includes one red pixel device and one green pixel device.

### Device Example 1

Preparation of the green pixel device: Firstly, a glass substrate with a thickness of 0.7 mm was provided. On the glass substrate, indium tin oxide (ITO) 75 Å/Ag 1500Å/ITO 150 Å were pre-patterned for use as an anode. The substrate was dried in a glovebox to remove moisture, mounted on a holder, and transferred into a vacuum chamber. The organic layers specified below were sequentially deposited through vacuum thermal evaporation on the anode layer at a rate of 0.01-10 Å/s and at a vacuum degree of about 10-6 Torr. Compound HT and Compound HI were co-deposited for use as a hole injection layer (HIL, 97:3, 100 Å). Compound HT was deposited for use as a hole transporting layer (HTL, about 1400 Å). Compound EB-1 was deposited for use as an electron blocking layer (EBL, about 50 Å). Compound GH-1, Compound GH-2, and Compound 99 were deposited on the EBL for use as an emissive layer (EML, 48:48:4, 400 Å). Compound HB was deposited for use as a hole blocking layer (HBL, 50 Å). Compound ET and Liq were co-deposited for use as an electron transporting layer (ETL, 40:60, 350 Å). A metal ytterbium (Yb) with a thickness of 10 Å was deposited for use as an electron injection layer (EIL). A metal magnesium (Mg) and a metal silver (Ag) were co-deposited for use as a cathode (10:90, 140 Å). Compound CPL-1 was deposited for use as a capping layer (CPL, 650 Å). The device was transferred back to the glovebox and encapsulated with a glass lid to complete the device.

Preparation of the red pixel device: The red pixel device was prepared by the same method as the green pixel device except that Compound HT was deposited for use as a hole transporting layer (HTL, about 1900 Å), Compound EB-2 was deposited for use as an electron blocking layer (EBL, about 50 Å), and Compound RH-1 and Compound 101 were deposited on the EBL for use as an emissive layer (EML, 97:3, 400 Å).

### Device Example 2

The green pixel device in Example 2 was prepared in the same manner as the green pixel device in Example 1.

The red pixel device in Example 2 was prepared in the same manner as that in Example 1 except that Compound RH-1 and Compound 102 were co-deposited to form an EML (97:3, 400 Å) of the red device.

### Device Example 3

The green pixel device in Example 3 was prepared in the same manner as the green pixel device in Example 1.

The red pixel device in Example 3 was prepared in the same manner as the red pixel device in Example 1 except that Compound RH-1 and Compound 103 were co-deposited to form an EML (97:3, 400 Å) of the red device.

### Device Example 4

The green pixel device in Example 4 was prepared in the same manner as the green pixel device in Example 1.

The red pixel device in Example 4 was prepared in the same manner as the red pixel device in Example 1 except that Compound RH-1 and Compound 104 were co-deposited to form an EML (97:3, 400 Å) of the red device.

### Device Example 5

The green pixel device in Example 5 was prepared in the same manner as the green pixel device in Example 1 except that Compound GH-1, Compound GH-2, and Compound 100 were co-deposited to form an EML (48:48:4, 400 Å) of the green device.

The red pixel device in Example 5 was prepared in the same manner as the red pixel device in Example 1.

### Device Example 6

The green pixel device in Example 6 was prepared in the same manner as the green pixel device in Example 5.

The red pixel device in Example 6 was prepared in the same manner as the red pixel device in Example 5 except that Compound RH-1 and Compound 102 were co-deposited to form an EML (97:3, 400 Å) of the red device.

### Device Example 7

The green pixel device in Example 7 was prepared in the same manner as the green pixel device in Example 5.

The red pixel device in Example 7 was prepared in the same manner as the red pixel device in Example 5 except that Compound RH-1 and Compound 103 were co-deposited to form an EML (97:3, 400 Å) of the red device.

### Device Example 8

The green pixel device in Example 8 was prepared in the same manner as the green pixel device in Example 5.

The red pixel device in Example 8 was prepared in the same manner as the red pixel device in Example 5 except that Compound RH-1 and Compound 104 were co-deposited to form an EML (97:3, 400 Å) of the red device.

### Device Comparative Example 1

The green pixel device in Comparative Example 1 was prepared in the same manner as the green pixel device in Example 1 except that Compound GH-1, Compound GH-2, and Compound GD were co-deposited to form an EML (45:45:10, 400 Å) of the green device.

The red pixel device in Comparative Example 1 was prepared in the same manner as the red pixel device in Example 1.

### Device Comparative Example 2

The green pixel device in Comparative Example 2 was prepared in the same manner as the green pixel device in Comparative Example 1.

The red pixel device in Comparative Example 2 was prepared in the same manner as the red pixel device in Comparative Example 1 except that Compound RH-1 and Compound 102 were co-deposited to form an EML (97:3, 400 Å) of the red device.

### Device Comparative Example 3

The green pixel device in Comparative Example 3 was prepared in the same manner as the green pixel device in Comparative Example 1.

The red pixel device in Comparative Example 3 was prepared in the same manner as the red pixel device in Comparative Example 1 except that Compound RH-1 and Compound 104 were co-deposited to form an EML (97:3, 400 Å) of the red device.

Detailed structures and thicknesses of emissive layers of the devices are shown in Table 6. Co-deposited compounds are shown at a weight ratio recorded.

TABLE 6
Structures of the emissive layers of the green pixel devices and the
red pixel devices in Examples 1 to 8 and Comparative Examples 1 to 3

| No. | EML of Green Pixel Device | EML of Red Pixel Device |
|---|---|---|
| Example 1 | Compound GH-1:Compound | Compound RH-1:Compound 101 |
| | GH-2:Compound 99 | (97:3) (400 Å) |
| | (48:48:4) (400 Å) | |
| Example 2 | Compound GH-1:Compound | Compound RH-1:Compound 102 |
| | GH-2:Compound 99 | (97:3) (400 Å) |
| | (48:48:4) (400 Å) | |
| Example 3 | Compound GH-1:Compound | Compound RH-1:Compound 103 |
| | GH-2:Compound 99 | (97:3) (400 Å) |
| | (48:48:4) (400 Å) | |
| Example 4 | Compound GH-1:Compound | Compound RH-1:Compound 104 |
| | GH-2:Compound 99 | (97:3) (400 Å) |
| | (48:48:4) (400 Å) | |
| Example 5 | Compound GH-1:Compound | Compound RH-1:Compound 101 |
| | GH-2:Compound 100 | (97:3) (400 Å) |
| | (48:48:4) (400 Å) | |
| Example 6 | Compound GH-1:Compound | Compound RH-1:Compound 102 |
| | GH-2:Compound 100 | (97:3) (400 Å) |
| | (48:48:4)(400 Å) | |
| Example 7 | Compound GH-1:Compound | Compound RH-1:Compound 103 |
| | GH-2:Compound 100 | (97:3) (400 Å) |
| | (48:48:4) (400 Å) | |
| Example 8 | Compound GH-1:Compound | Compound RH-1:Compound 104 |
| | GH-2:Compound 100 | (97:3) (400 Å) |
| | (48:48:4)(400 Å) | |
| Comparative | Compound GH-1:Compound | Compound RH-1:Compound 101 |
| Example 1 | GH-2:Compound GD | (97:3) (400 Å) |
| | (45:45:10)(400 Å) | |
| Comparative | Compound GH-1:Compound | Compound RH-1:Compound 102 |
| Example 2 | GH-2:Compound GD | (97:3) (400 Å) |
| | (45:45:10)(400 Å) | |
| Comparative | Compound GH-1:Compound | Compound RH-1:Compound 104 |
| Example 3 | GH-2:Compound GD | (97:3) (400 Å) |
| | (45:45:10)(400 Å) | |

The materials used in the devices have the following structures:

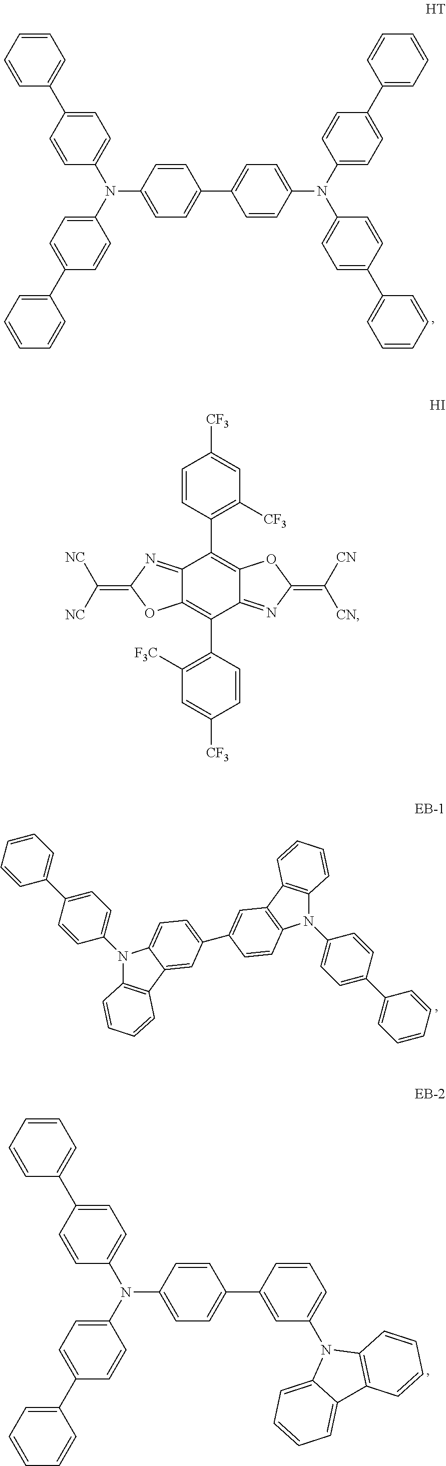

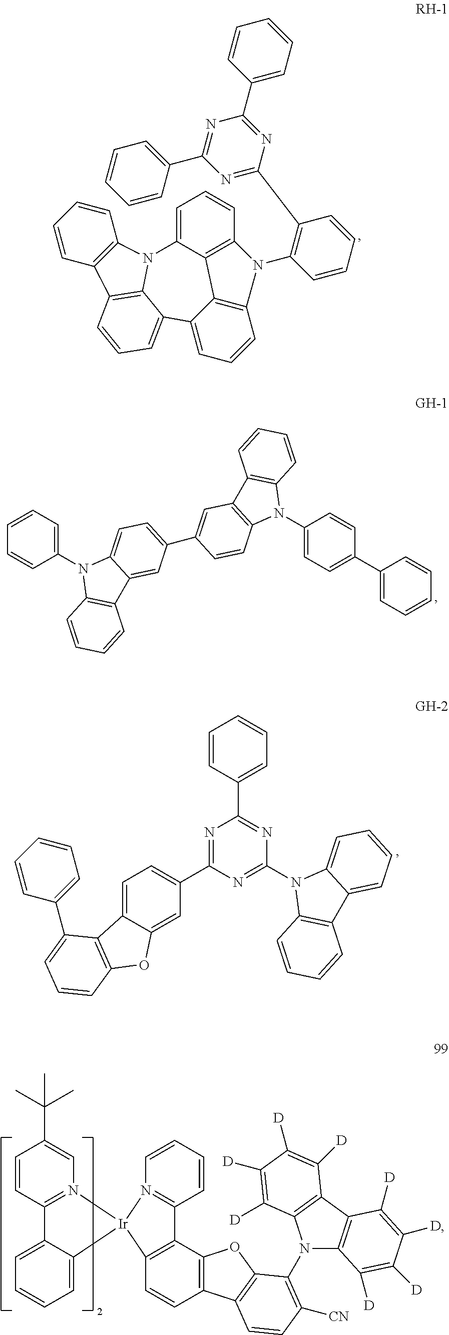

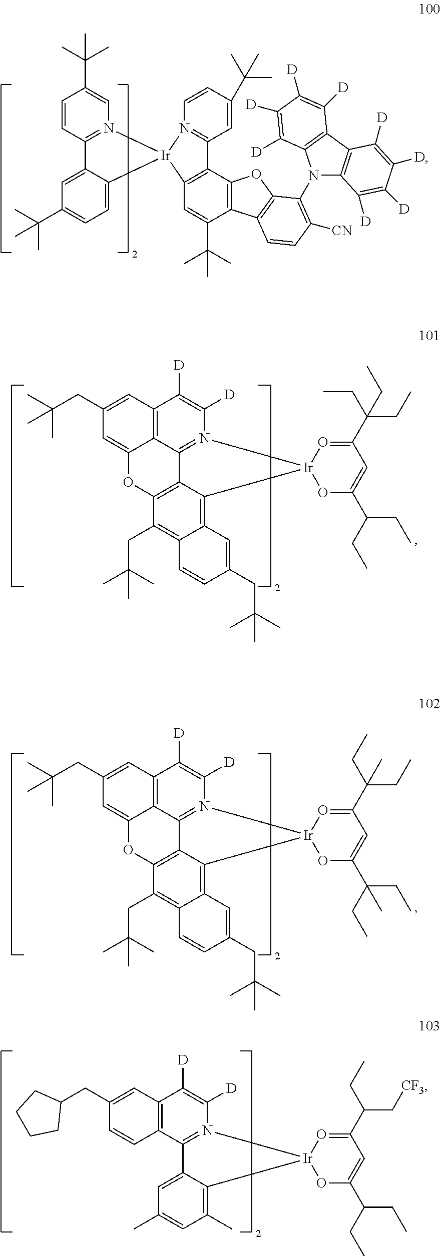

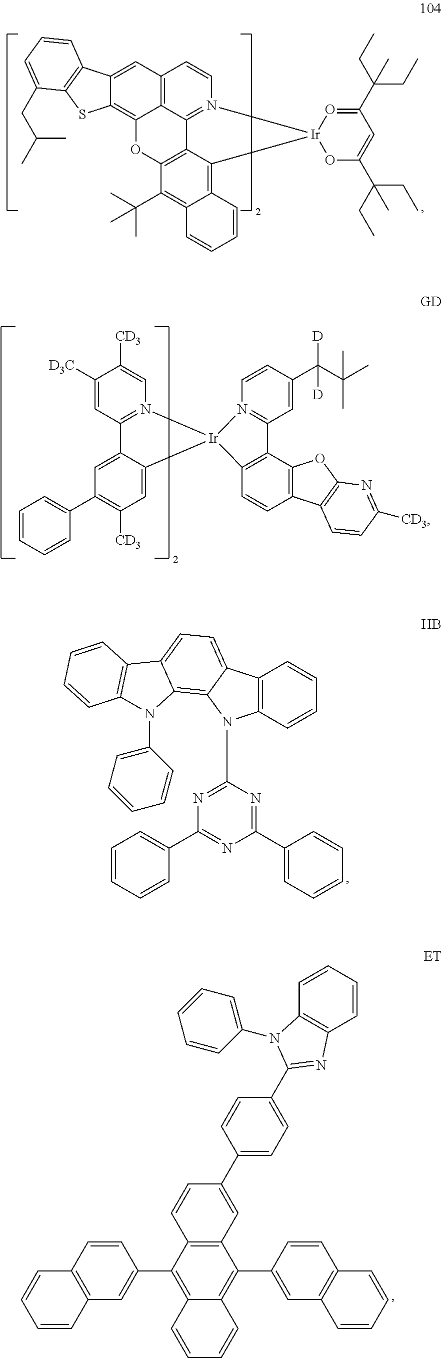

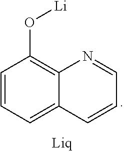

Compound CPL-1 is a material of the capping layer purchased from Jiangsu Sunera Technology Co., Ltd. (refractive index n@630 nm is 1.95).

The maximum emission wavelengths λ1 and λ2 [nm] and the FWHMs FWHM1 and FWHM2 [nm] of the PL spectra of the green and red light-emitting materials used in Device Examples 1 to 8 and Device Comparative Examples 1 to 3 and the difference between the FWHMs of the PL spectra of the red and green light-emitting materials (ΔFWHM, ΔFWHM=FWHM2−FWHM1) are recorded in Table 7.

TABLE 7
PL spectrum data of the red and green light-emitting materials used
in Device Examples 1 to 8 and Device Comparative Examples 1 to 3

| | PL Spectrum Parameter of | | | PL Spectrum Parameter of | | | |
|---|---|---|---|---|---|---|---|
| | Light-Emitting Material in Green | | | Light-Emitting Material in Red | | | |
| | Pixel Device | | | Pixel Device | | | ΔFWHM |
| | | λ1 | FWHM1 | | λ2 | FWHM2 | (FWHM2 − |
| Device No. | Compound No. | [nm] | [nm] | Compound No. | [nm] | [nm] | FWHM1) |
| Example 1 | Compound 99 | 528 | 31 | Compound 101 | 619 | 30 | −1 |
| Example 2 | Compound 99 | 528 | 31 | Compound 102 | 619 | 31 | 0 |
| Example 3 | Compound 99 | 528 | 31 | Compound 103 | 619 | 40 | 9 |
| Example 4 | Compound 99 | 528 | 31 | Compound 104 | 624 | 31 | 0 |
| Example 5 | Compound 100 | 522 | 29 | Compound 101 | 619 | 30 | 1 |
| Example 6 | Compound 100 | 522 | 29 | Compound 102 | 619 | 31 | 2 |
| Example 7 | Compound 100 | 522 | 29 | Compound 103 | 619 | 40 | 11 |
| Example 8 | Compound 100 | 522 | 29 | Compound 104 | 624 | 31 | 2 |
| Comparative | Compound GD | 525 | 52 | Compound 101 | 619 | 30 | −22 |
| Example 1 | | | | | | | |
| Comparative | Compound GD | 525 | 52 | Compound 102 | 619 | 31 | −21 |
| Example 2 | | | | | | | |
| Comparative | Compound GD | 525 | 52 | Compound 104 | 624 | 31 | −21 |
| Example 3 | | | | | | | |

The luminance (L0) corresponding to the green and red pixel devices in Device Examples 1 to 8 and Device Comparative Examples 1 to 3 at a viewing angle of 0°, the luminance (L30) corresponding to the green and red pixel devices at a viewing angle of 30°, the luminance decay values (D1, D1=L30/L0, that is, the ratio of the luminance at 30° to the luminance at 0°, which are obtained through actual device measurements) corresponding to the green and red pixel devices at a viewing angle of 30°, and the calculated luminance decay differences (ΔD, ΔD=D1−D2) of the green and red pixel devices are recorded in Table 8.

TABLE 8
Luminance and luminance decay data of the red
and green pixel devices in Device Examples 1
to 8 and Device Comparative Examples 1 to 3

| | Green Pixel Device | | | Red Pixel Device | | | |
|---|---|---|---|---|---|---|---|
| Device No. | L0 | L30 | D1 | L0 | L30 | D2 | ΔD |
| Example 1 | 20318 | 11910 | 59% | 5671 | 3108 | 55% | 4% |
| Example 2 | 20318 | 11910 | 59% | 7305 | 4240 | 58% | 1% |
| Example 3 | 20318 | 11910 | 59% | 6655 | 4822 | 72% | −13% |
| Example 4 | 20318 | 11910 | 59% | 7288 | 3952 | 54% | 5% |
| Example 5 | 19773 | 12373 | 63% | 5671 | 3108 | 55% | 8% |
| Example 6 | 19773 | 12373 | 63% | 7305 | 4240 | 58% | 5% |
| Example 7 | 19773 | 12373 | 63% | 6655 | 4822 | 72% | −9% |
| Example 8 | 19773 | 12373 | 63% | 7288 | 3952 | 54% | 9% |
| Comparative | 17551 | 15034 | 86% | 5671 | 3108 | 55% | 31% |
| Example 1 | | | | | | | |
| Comparative | 17551 | 15034 | 86% | 7305 | 4240 | 58% | 28% |
| Example 2 | | | | | | | |
| Comparative | 17551 | 15034 | 86% | 7288 | 3952 | 54% | 32% |
| Example 3 | | | | | | | |

It is generally thought in the industry that when the luminance decay values D of devices of different colors in the display panel differ within a range of 15%, the display panel can basically maintain the uniform luminance decay and has a relatively small color cast. As can be known from the data in Table 7 and Table 8, the green pixel devices in Examples 1 to 4 of the present disclosure were prepared in the same manner, the doped material used the EML was a green light-emitting doped material Compound 99, the PL spectrum of Compound 99 had a maximum emission wavelength of 528 nm and a full width at half maximum FWHM1 of 31 nm, and the corresponding luminance decay value D1 of the green pixel devices was 59%. Examples 1 to 4 differed only in that the EML of the red pixel device used a red light-emitting doped material, where the difference between the FWHMs of the red light-emitting doped material and the green light-emitting doped material was within a particular range.

Specifically, in Example 1, the used red light-emitting doped material was Compound 101, the PL spectrum of Compound 101 had a maximum emission wavelength of 619 nm and a full width at half maximum FWHM2 of 30 nm, the difference ΔFWHM between the FWHMs of Compound 101 and the green light material Compound 99 was 30 nm−31 nm=−1 nm, that is, the FWHMs of Compound 101 and Compound 99 were relatively close. In this case, at the viewing angle of 30°, the luminance decay value D2 corresponding to the red device in Example 1 was 55%, the luminance decay value D1 corresponding to the green pixel device was 59%, and the luminance decay difference ΔD=59%−55%=4%, that is, the luminance decay values of red light and green light were relatively close.

Similarly, in Example 2, the used red light-emitting doped material was Compound 102, the PL spectrum of Compound 102 had a maximum emission wavelength of 619 nm and a full width at half maximum FWHM2 of 31 nm, the difference ΔFWHM between the FWHMs of Compound 102 and Compound 99 was 31 nm−31 nm=0 nm, that is, the FWHMs were the same. In this case, in Example 2, the luminance decay value D2 corresponding to the red device was 58% and the luminance decay difference ΔD between the red device and the green pixel device was 1%, that is, the luminance decay values of red light and green light almost identical. Similarly, in Example 3, the used red light-emitting doped material was Compound 103, the PL spectrum of Compound 103 had a maximum emission wavelength of 619 nm and a full width at half maximum FWHM2 of 40 nm, the difference ΔFWHM between the FWHMs of Compound 103 and Compound 99 was 40 nm−31 nm=9 nm, that is, the FWHM of the green material was 9 nm narrower than that of the red material. In this case, in Example 3, the luminance decay value D2 corresponding to the red device was 72% and the luminance decay difference ΔD between the red device and the green pixel device was −13%, that is, the luminance decay values of red light and green light were relatively close. In Example 4, the used red light-emitting doped material was Compound 104, the PL spectrum of Compound 104 had a maximum emission wavelength of 624 nm and a full width at half maximum FWHM2 of 31 nm, the difference ΔFWHM between the FWHMs of Compound 104 and Compound 99 was 31 nm−31 nm=0 nm, that is, the FWHM of the green material was consistent with that of the red material. In this case, in Example 4, the luminance decay value D2 corresponding to the red device was 54% and the luminance decay difference ΔD between the red device and the green pixel device was −5%, that is, the luminance decay values of red light and green light were relatively close.

As can be known from the preceding data, in Device Examples 1 to 4 of the present disclosure, the red light and green light pixel devices all have luminance decays which are basically the same, and when the red light and green light pixel devices are applied to the display panel, an image presented at a large angle will not become greener or redder for the stronger decay of one of the red light and green light pixel devices, thereby ensuring the performance of a good color presented at different viewing angles.

In addition, it is to be particularly noted that in Examples 1 to 4, the luminance of the green light devices decayed from 20318 nits at the viewing angle of 0° to 11910 nits at the viewing angle of 30°; although D1 of the green light device is relatively large, the decayed luminance can still reach more than 10000 nits since the luminance at the viewing angle of 0° is relatively high, thereby presenting relatively strong light. For the red light device, the luminance of the red light devices in Examples 1 to 4 at the viewing angle of 30° was 3108 nits, 4240 nits, 4822 nits, and 3952 nits, respectively, and the decayed luminance can reach more than 3000 nits so that relatively strong light can still be presented, and a requirement of human eyes on the panel luminance during use can be completely satisfied. Thus, user experience will not become worse for luminance decays at different viewing angles.

In the red and green light devices in Device Examples 5 to 8, the red and green light-emitting materials whose FWHMs have a difference satisfying a particular relationship (FWHM2−FWHM1≥−15 nm) were also selected. As can be seen from the data in Table 8, the luminance decay degrees of red light and green light in Examples 5 to 8 were relatively close (the absolute values of ΔD were all less than or equal to 9%). Therefore, an image with a relatively good color can be presented at different viewing angles.

It is to be noted that the green light-emitting doped material Compound GD used in Comparative Examples 1 to 3 is a material used in current commercial applications, the PL spectrum of Compound GD had a maximum emission wavelength of 525 nm and a relatively wide full width at half maximum FWHM1 of 52 nm, and the luminance decay value D1 corresponding to the green light device was 86%, that is, the decay was relatively weak. In Comparative Examples 1 to 3, Compound GD with a relatively wide FWHM was matched with the red light-emitting materials Compound 101, Compound 102, and Compound 104 with relatively narrow FWHMs, the differences between the FWHMs were −22 nm, −21 nm, and −21 nm, respectively, and the luminance decay differences were 31%, 28%, and 32%, respectively. That is, the luminance decays of red light and green light had a relatively large difference, which were inconsistent. In this case, at the viewing angle of 30°, an image presented by the display panel became greener for the weaker decay of green light and the stronger decay of red light, thereby causing a color distortion and poor user experience.

The preceding data show that in Device Examples 1 to 8 where a combination of red and green light-emitting materials satisfying that FWHM2 (red light-emitting doped material)−FWHM1 (green light-emitting doped material)≥−15 nm is selected, the luminance decay degrees of the red and green pixel devices have a relatively small difference so that the problem of the color cast of the display panel including the red and green pixel devices at different viewing angles can be effectively solved, and the display panel has a wide application prospect.

To conclude, in the present disclosure, a match and combination of red and green light-emitting materials whose FWHMs of PL spectra have a difference within a particular range (FWHM2−FWHM1≥−15 nm) are selected to be applied to devices of the display panel having pixels of different colors, ensuring that the luminance decay degrees of red light and green light are basically the same at a different viewing angle. Thus, an image displayed by the display panel will not become greener or redder for the stronger decay of one of red light and green light so that an image with a relatively good color is presented at a different viewing angle.

Of course, the display panel generally includes sub-pixels of at least three colors of red, green, and blue, the color cast at a large viewing angle is directly related to luminance decays of sub-pixels. The FWHM of the currently commercial blue light is generally less than 35 nm. Therefore, a luminance decay occurs at a large viewing angle. To ensure the stability of the white balance at a large viewing angle, the luminance decay degrees of the three red, green, and blue sub-pixels at the large viewing angle should be as consistent as possible. Therefore, the above-explored spectrum relationship between red and green pixels is also applicable to a blue light pixel, that is, FWHM1 (green light-emitting doped material)−FWHM3 (blue light-emitting doped material)≥−15 nm; preferably, 15 nm≥FWHM1−FWHM3≥−15 nm; more preferably, 3 nm≥FWHM1−FWHM3≥−3 nm; still more preferably, FWHM1−FWHM3≥0 nm. In addition, since the red and green pixels are both continuously developed towards narrow spectra, it can be seen from the preceding simulations that when the luminance decay degree is the same, a bluer sub-pixel is required to have a narrower spectrum FWHM. Therefore, if the FWHMs of the red and green sub-pixels are narrowed to 30 nm, the FWHM of the blue sub-pixel needs to be less than 30 nm, that is, FWHM3≤30 nm; preferably, FWHM3≤28 nm; more preferably, FWHM3≤25 nm.

To conclude, according to the content disclosed in the present disclosure, a combination and match of light-emitting materials of different colors whose FWHMs have a difference within a particular range are selected to be applied to pixels of different colors in the display panel so that the luminance decay degrees can be basically consistent, the performance of different pixels in the display panel at a large viewing large can be coordinated while the efficiency and color purity of an OLED are ensured, and the color cast is further improved, achieving a broad application prospect.

It is to be understood that various embodiments described herein are merely illustrative and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limiting.

What is claimed is:

1. An organic electroluminescent display panel, comprising a base substrate on which at least two organic electroluminescent devices are disposed;
a first organic electroluminescent device comprising a first anode, a first cathode, and a first light-emitting layer disposed between the first anode and the first cathode, wherein the first light-emitting layer comprises a first light-emitting doped material whose photoluminescence spectrum has a maximum emission wavelength λ1 and a full width at half maximum FWHM1; and
a second organic electroluminescent device comprising a second anode, a second cathode, and a second light-emitting layer disposed between the second anode and the second cathode, wherein the second light-emitting layer comprises a second light-emitting doped material whose photoluminescence spectrum has a maximum emission wavelength λ2 and a full width at half maximum FWHM2;
wherein 500 nm≤λ1<600 nm and λ2≥600 nm; and
FWHM1 and FWHM2 are each less than or equal to 40 nm, and FWHM2−FWHM1≥−15 nm.

2. The organic electroluminescent display panel according to claim 1, wherein 15 nm≥FWHM2−FWHM1≥−15 nm;
preferably, 8 nm≥FWHM2−FWHM1≥−8 nm; more preferably, 5 nm≥FWHM2−FWHM1≥−5 nm; most preferably, 3 nm≥FWHM2−FWHM1≥−3 nm.

3. The organic electroluminescent display panel according to claim 1, wherein FWHM2−FWHM1≥0.

4. The organic electroluminescent display panel according to claim 1, wherein at least one of FWHM1 and FWHM2 is less than or equal to 35 nm;
preferably, at least one of FWHM1 and FWHM2 is less than or equal to 30 nm;
more preferably, 20 nm≤FWHM1≤30 nm and 20 nm≤FWHM2≤30 nm.

5. The organic electroluminescent display panel according to claim 1, wherein 500 nm≤λ1<560 nm; preferably, 500 nm≤λ1<535 nm; more preferably, 515 nm≤λ1<535 nm.

6. The organic electroluminescent display panel according to claim 1, wherein 600 nm≤λ2 <650 nm; preferably, 610 nm≤λ2<640 nm; more preferably, 615 nm≤λ2<640 nm.

7. The organic electroluminescent display panel according to claim 1, wherein the first organic electroluminescent device and the second organic electroluminescent device are each a top-emitting device.

8. The organic electroluminescent display panel according to claim 1, wherein the first organic electroluminescent device comprises a first capping layer, the second organic electroluminescent device comprises a second capping layer, and preferably, the first capping layer and the second capping layer have a same material and/or thickness.

9. The organic electroluminescent display panel according to claim 1, wherein the first cathode and the second cathode have a same thickness and/or material; preferably, the first cathode and the second cathode are a same electrode.

10. The organic electroluminescent display panel according to claim 1, wherein the first cathode and the second cathode each comprise Yb, Mg, Ag, MoOx, Yb, Ca, ITO, IZO, or a combination thereof,
preferably, the first cathode and the second cathode each comprise a composition of Mg and Ag, and a mass ratio of Mg to Ag in the composition is 0.5:9.5-2:8.

11. The organic electroluminescent display panel according to claim 1, wherein the first anode and the second anode are each selected from Ag, Al, Ti, Cr, Pt, Ni, TiN, ITO, MoOx, or a combination thereof,
preferably, the anode has a reflectivity of greater than 50%;
more preferably, the anode has a reflectivity of greater than 70%.

12. The organic electroluminescent display panel according to claim 1, wherein the first light-emitting doped material and/or the second light-emitting doped material are each a phosphorescent doped material.

13. The organic electroluminescent display panel according to claim 12, wherein the phosphorescent doped material is a metal complex.

14. The organic electroluminescent display panel according to claim 1, further comprising a third organic electroluminescent device on the base substrate, wherein the third organic electroluminescent device comprises a third light-emitting layer, and the third light-emitting layer comprises a third light-emitting doped material whose photoluminescence spectrum has a maximum emission wavelength λ3 and a full width at half maximum FWHM3, wherein FWHM3<35 nm, 400≤λ3<500 nm, and FWHM1−FWHM3≥−15 nm;
preferably, 15 nm≥FWHM1−FWHM3≥−15 nm;
more preferably, 3 nm≥FWHM1−FWHM3≥−3 nm;
most preferably, FWHM1−FWHM3≥0 nm.

15. The organic electroluminescent display panel according to claim 14, wherein FWHM3≤30 nm; preferably, FWHM3≤28 nm; more preferably, FWHM3≤25 nm.

16. The organic electroluminescent display panel according to claim 14, wherein the third light-emitting layer may further comprise a fourth light-emitting doped material, and at least one of the fourth light-emitting doped material and the third light-emitting doped material is selected from a phosphorescent doped material.

17. The organic electroluminescent display panel according to claim 1, wherein the base substrate is selected from glass, polyimide, or silicon.

18. The organic electroluminescent display panel according to claim 1, wherein a luminance decay value of the first organic electroluminescent device at a viewing angle of 30° is D1 and a luminance decay value of the second organic electroluminescent device at a viewing angle of 30° is D2;
wherein −15%≤D1−D2≤15%; preferably, −10%≤D1−D2≤10%.

19. An electronic assembly, comprising the organic electroluminescent display panel according to claim 1.
